(19) United States
(12) Patent Application Publication
(10) Pub. No.: US 2026/0068629 A1
(43) Pub. Date: Mar. 5, 2026

(54) SEMICONDUCTOR DEVICE

(71) Applicant: Samsung Electronics Co., Ltd., Suwon-si (KR)

(72) Inventors: Hojun Choi, Suwon-si (KR); Hyunjun Bae, Suwon-si (KR); Jisoo Kim, Suwon-si (KR); Jinkyu Kim, Suwon-si (KR); KyuTae Jeong, Suwon-si (KR); Dong-Hwan Han, Suwon-si (KR)

(21) Appl. No.: 19/093,357

(22) Filed: Mar. 28, 2025

(30) Foreign Application Priority Data
Aug. 27, 2024 (KR) 10-2024-0115411

(51) Int. Cl. H01L 23/522; H01L 23/00; H01L 23/528; H01L 23/538; H01L 25/18; H10D 30/00; H10D 30/01; H10D 30/43; H10D 62/10; H10D 62/13; H10D 64/23; H10D 84/01; H10D 84/85

(52) U.S. Cl. CPC H01L 23/5226; H10D 30/014; H10D 30/0191; H10D 30/43; H10D 30/502; H10D 62/121; H10D 62/151; H10D 64/256; H10D 84/0186; H10D 84/851

(57) ABSTRACT

A semiconductor device includes a substrate comprising a logic cell region and a peripheral region extending around the logic cell region, a logic device in the logic cell region and comprising a plurality of source/drain patterns, an upper active contact on and electrically connected to one of the source/drain patterns, a lower active contact below and electrically connected to another of the source/drain patterns, a conductive structure that penetrates the peripheral region of the substrate, a plurality of peripheral upper wiring lines in the peripheral region and connected to the conductive structure, and a plurality of peripheral lower wiring lines in the peripheral region and connected to the conductive structure opposite the peripheral upper wiring lines. A bottom surface of the conductive structure is lower than a bottom surface of the lower active contact, relative to a bottom surface of the substrate.

### CROSS-REFERENCE TO RELATED APPLICATION

This application claims priority under 35 U.S.C. § 119 to Korean Patent Application No. 10-2024-0115411 filed on Aug. 27, 2024, in the Korean Intellectual Property Office, the disclosure of which is hereby incorporated by reference in its entirety.

### TECHNICAL FIELD

The present inventive concepts relate to a semiconductor device, and more particularly, to a semiconductor device including a field effect transistor.

### BACKGROUND

A semiconductor device may include an integrated circuit with metal oxide semiconductor field effect transistors (MOSFETs). As size and design rule of the semiconductor device are gradually decreased, sizes of the MOSFETs are also increasingly scaled down. The downscaling of MOSFETs may deteriorate operating characteristics of the semiconductor device. Accordingly, research and development efforts have been directed to manufacturing semiconductor devices having excellent performance while addressing limitations due to higher integration of the semiconductor device.

### SUMMARY

Some embodiments of the present inventive concepts provide a semiconductor device whose fabrication process is simplified. Embodiments of the present inventive concepts are not limited to the mentioned above, and other embodiments which have not been mentioned above will be clearly understood to those skilled in the art from the following description.

According to some embodiments of the present inventive concepts, a semiconductor device may comprise: a substrate that comprises a logic cell region and a peripheral region extending around the logic cell region; a logic device in the logic cell region and comprising a plurality of source/drain patterns; an upper active contact on and electrically connected to one of the source/drain patterns; a lower active contact below and electrically connected to another of the source/drain patterns; a conductive structure that penetrates the peripheral region of the substrate; a plurality of peripheral upper wiring lines in the peripheral region and connected to the conductive structure; and a plurality of peripheral lower wiring lines in the peripheral region and connected to the conductive structure opposite the peripheral upper wiring lines. A bottom surface of the conductive structure may be lower than a bottom surface of the lower active contact, relative to a bottom surface of the substrate.

According to some embodiments of the present inventive concepts, a semiconductor device may comprise: a substrate that comprises a logic cell region and a peripheral region extending around the logic cell region; a plurality of source/drain patterns on the logic cell region; a channel pattern between ones of the source/drain patterns and comprising a plurality of semiconductor patterns that are stacked and spaced apart from each other in a direction perpendicular to a top surface of the substrate; a gate electrode on the channel pattern; a gate capping pattern on a top surface of the gate electrode; a first interlayer dielectric layer on the top surface of the substrate and on the source/drain patterns; a second interlayer dielectric layer that on a top surface of the first interlayer dielectric layer and on a top surface of the gate capping pattern; a third interlayer dielectric layer on a bottom surface of the substrate that is opposite the top surface of the substrate; a plurality of upper active contacts that penetrate the first and second interlayer dielectric layers and are electrically connected to a first subset of the source/drain patterns; a plurality of lower active contacts that penetrate the third interlayer dielectric layer and the substrate and are electrically connected to a second subset of the source/drain patterns; first and second upper dielectric layers that are sequentially stacked on a top surface of the second interlayer dielectric layer; first, second, and third lower dielectric layers that are sequentially stacked on a bottom surface of the third interlayer dielectric layer; a conductive structure that penetrates the peripheral region of the substrate and the first, second, and third interlayer dielectric layers; a plurality of peripheral upper wiring lines in the peripheral region, wherein the peripheral upper wiring lines penetrate the first and second upper dielectric layers to connect to the conductive structure; and a plurality of peripheral lower wiring lines in the peripheral region, wherein the peripheral lower wiring lines penetrate the first, second, and third lower dielectric layers to connect to the conductive structure opposite the peripheral upper wiring lines. The conductive structure may penetrate the first upper dielectric layer and at least a portion of the first lower dielectric layer.

According to some embodiments of the present inventive concepts, a semiconductor device may comprise: a redistribution substrate; and a first semiconductor chip and a second semiconductor chip stacked on the redistribution substrate such that the first semiconductor chip is between the redistribution substrate and the second semiconductor chip. The first semiconductor chip may comprise: a substrate that comprises a logic cell region and a peripheral region extending around the logic cell region; a plurality of source/drain patterns on the logic cell region; a channel pattern between ones of the source/drain patterns, wherein the channel pattern comprises a plurality of semiconductor patterns that are stacked and spaced apart from each other in a direction perpendicular to a top surface of the substrate; a plurality of upper active contacts on and electrically connected to a first subset of the source/drain patterns; a plurality of lower active contacts on and electrically connected to a second subset of the source/drain patterns; a conductive structure that penetrates the peripheral region of the substrate; a plurality of peripheral upper wiring lines in the peripheral region of the substrate and connected to the conductive structure; and a plurality of peripheral lower wiring lines in the peripheral region of the substrate and electrically connected to the conductive structure opposite the peripheral upper wiring lines. The conductive structure, the peripheral upper wiring lines, and the peripheral lower wiring lines may electrically connect the redistribution substrate and the second semiconductor chip to each other.

### BRIEF DESCRIPTION OF DRAWINGS

FIGS. 1 and 2 illustrate conceptual diagrams showing a semiconductor device according to some embodiments of the present inventive concepts.

FIG. 3 illustrates a plan view showing a semiconductor device according to some embodiments of the present inventive concepts.

FIG. 4 illustrates a plan view showing a logic cell region and a peripheral region of FIG. 3.

FIGS. 5A, 5B, 5C, 5D, and 5E illustrate cross-sectional views respectively taken along lines A-A′, B-B′, C-C′, D-D′, and E-E′ of FIG. 4.

FIG. 6 illustrates a cross-sectional views showing a semiconductor device according to some embodiments of the present inventive concepts, which corresponds to FIG. 5E.

FIG. 7 illustrates a cross-sectional view showing a semiconductor device according to some embodiments of the present inventive concepts.

FIG. 8 illustrates an enlarged view showing section P1 of FIG. 7.

FIGS. 9A, 9B, 9C, 10A, 10B, 11A, 11B, 11C, 11D, 12A, 12B, 12C, 13A, 13B, 13C, 13D, 14A, 14B, 14C, 14D, 14E, 15A, 15B, 15C, 15D, 15E, 16A, 16B, 16D, 16E, 17A 17B, 17C, 17D, and 17E illustrate diagrams showing a method of fabricating a semiconductor device according to some embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts. Like reference numerals may indicate like components throughout the description. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Spatially relative terms, such as “top,” “above,” “upper,” “upper portion,” “upper surface,” “bottom,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures.

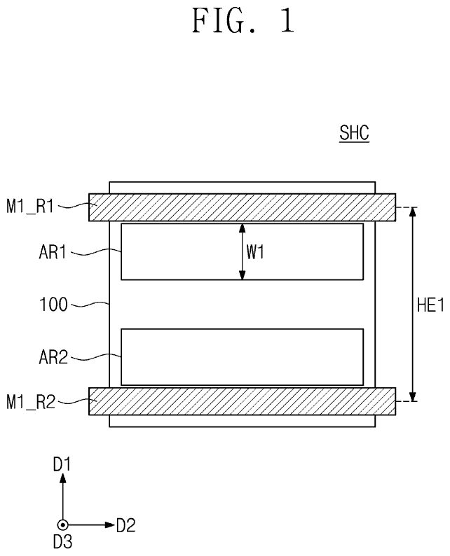

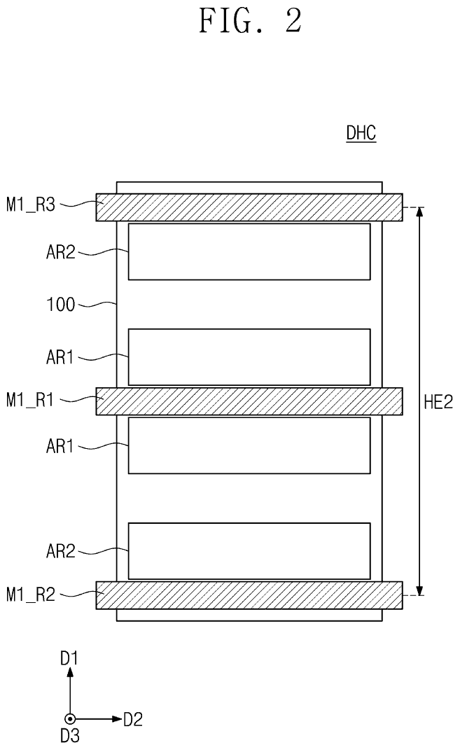

FIGS. 1 and 2 illustrate conceptual diagrams showing a semiconductor device according to some embodiments of the present inventive concepts.

Referring to FIG. 1, a single height cell SHC may be provided. A first power line M1_R1 and a second power line M1_R2 may be provided on a substrate 100. For example, the first power line M1_R1 may be a path for providing a source voltage or a ground voltage. The second power line M1_R2 may be a path for providing a drain voltage or a power voltage.

The single height cell SHC may be defined between the first power line M1_R1 and the second power line M1_R2. The single height cell SHC may include a first active region AR1 and a second active region AR2. For example, one of the first active region AR1 and the second active region AR2 may be a PMOSFET region. The other of the first active region AR1 and the second active region AR2 may be an NMOSFET region. In this configuration, the single height cell SHC may have a complementary metal oxide semiconductor (CMOS) structure provided between the first power line M1_R1 and the second power line M1_R2.

Each of the first and second active regions AR1 and AR2 may have a first width W1 in a first direction D1. A first height HE1 may refer to a length in the first direction D1 of the single height cell SHC. The first height HE1 may be substantially the same as a distance (e.g., pitch) between the first power line M1_R1 and the second power line M1_R2.

The single height cell SHC may constitute one logic cell. In this description, the logic cell may indicate a logic device, such as AND, OR, XOR, XNOR, and inverter, that performs a specific function. For example, the logic cell may include transistors for constituting a logic device and wiring lines that connect the transistors to each other.

Referring to FIG. 2, a double height cell DHC may be provided. A substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage.

The double height cell DHC may be defined between the second power line M1_R2 and the third power line M1_R3. The double height cell DHC may include two first active regions AR1 and two second active regions AR2.

The first active regions AR1 may be adjacent to the first power line M1_R1. One of the second active regions AR2 may be adjacent to the second power line M1_R2. The other of the second active regions AR2 may be adjacent to the third power line M1_R3. When viewed in plan view, the first power line M1_R1 may be positioned between the two first active regions AR1.

A second height HE2 may be defined to refer to a length in the first direction D1 of the double height cell DHC. The second height HE2 may be about twice the first height HE1 of FIG. 1. For example, the first active regions AR1 of the double height cell DHC may collectively serve as one PMOSFET region. Therefore, the double height cell DHC may have a PMOS transistor whose channel size is greater than that of a PMOS transistor included in the single height cell SHC of FIG. 1.

For example, the channel size of the PMOS transistor included in the double height cell DHC may be about twice that of the PMOS transistor included in the single height cell SHC. In conclusion, the double height cell DHC may operate at a higher speed than that of the single height cell SHC.

In this description, the double height cell DHC shown in FIG. 2 may be defined as a multi-height cell. Although not shown, the multi-height cell may include a triple height cell whose cell height is about three times that of the single height cell SHC.

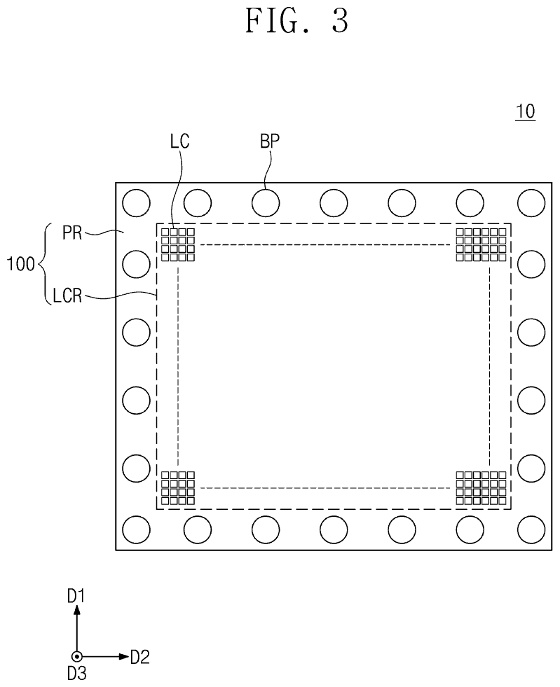

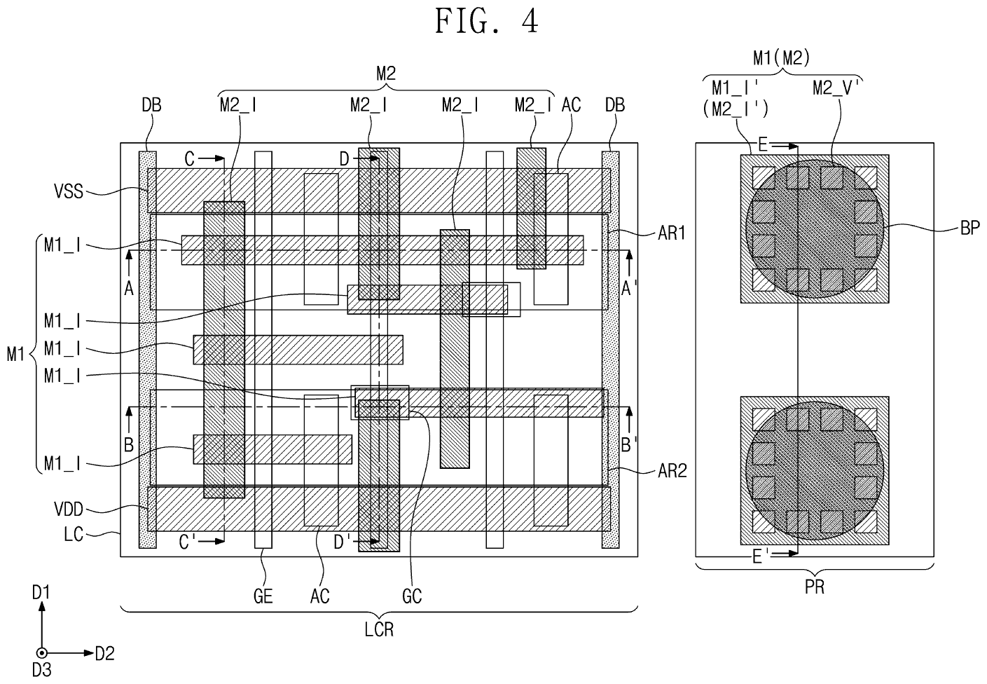

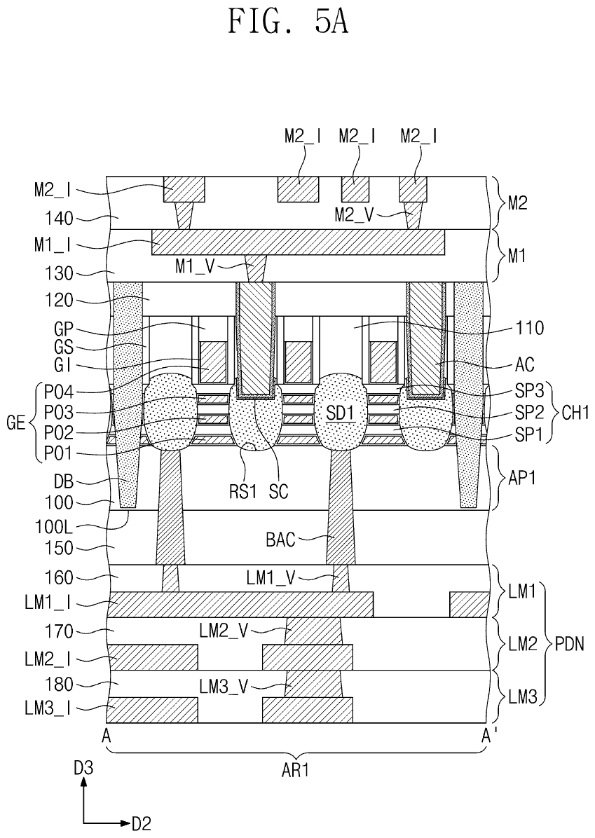

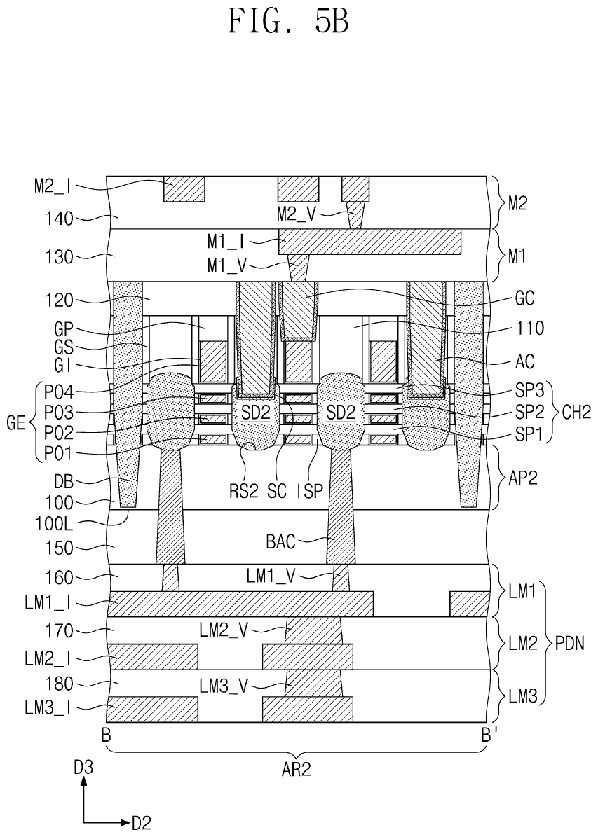

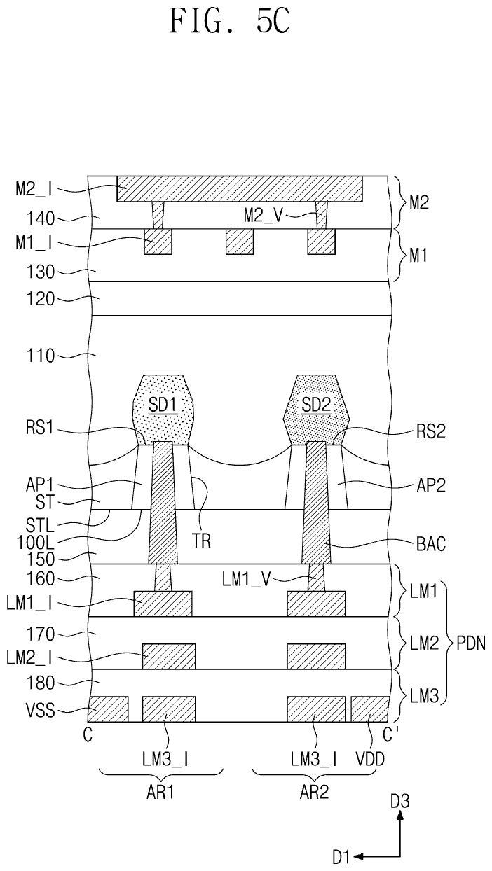

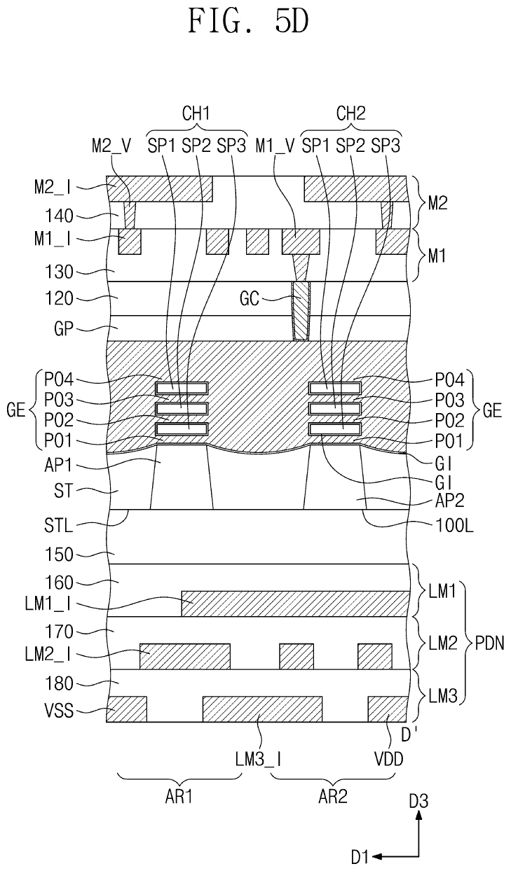

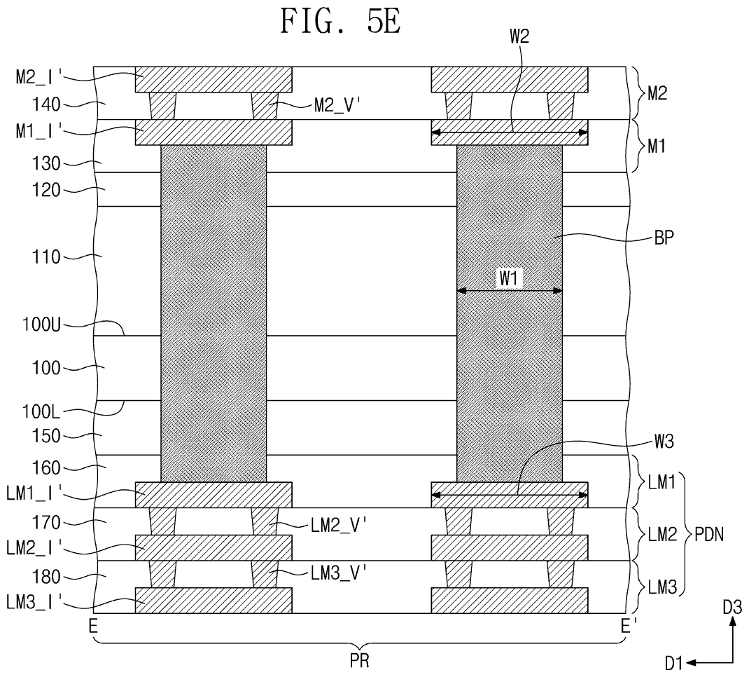

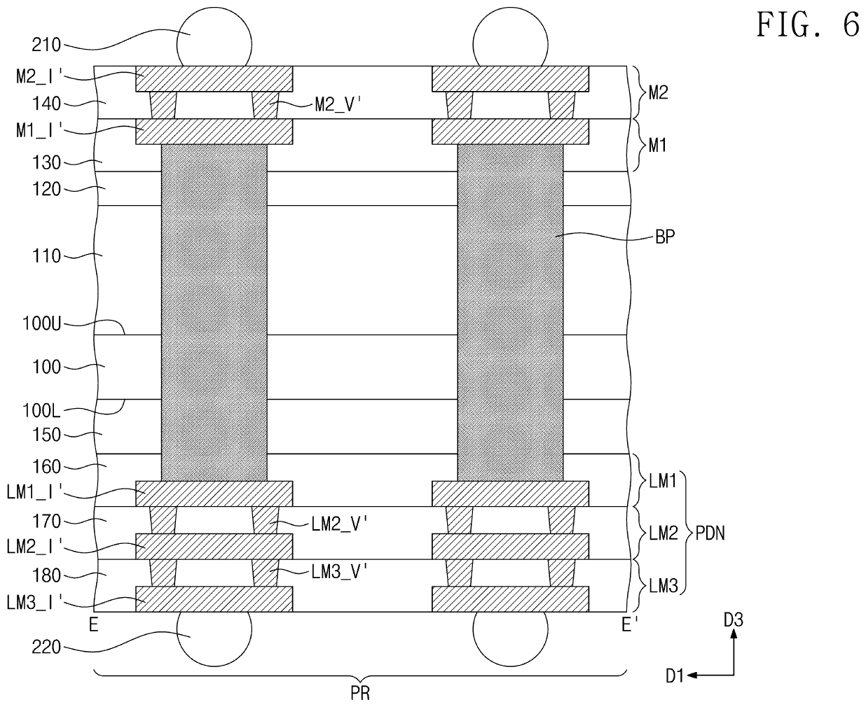

FIG. 3 illustrates a plan view showing a semiconductor device according to some embodiments of the present inventive concepts. FIG. 4 illustrates a plan view showing a logic cell region and a peripheral region of FIG. 3. FIGS. 5A, 5B, 5C, 5D, and 5E illustrate cross-sectional views respectively taken along lines A-A′, B-B′, C-C′, D-D′, and E-E′ of FIG. 4.

Referring to FIGS. 3 and 4, a first semiconductor chip 10 according to the present inventive concepts may include a substrate 100. The substrate 100 may include a logic cell region LCR and a peripheral region PR that surrounds the logic cell region LCR. The term “surround” (or “cover” or “fill”) as may be used herein may not require completely surrounding (or covering or filling) the described elements or layers, but may, for example, refer to partially surrounding (or covering or filling) the described elements or layers, for example, with gaps, spaces, or other discontinuities throughout. A plurality of logic cells LC may be disposed on the logic cell region LCR. For example, the logic cell LC may be the single height cell SHC discussed with reference to FIG. 1. The logic cell LC may be provided thereon with logic devices included in a logic circuit.

The peripheral region PR may indicate a section that surrounds the logic cell region LCR, and for example, may be an edge part of the substrate 100. The peripheral region PR may be provided thereon with conductive structures BP. When viewed in plan view, the conductive structures BP may be spaced apart from each other along first and second directions D1 and D2 that are parallel to a bottom surface of the substrate 100. In addition, FIG. 3 depicts that the conductive structures BP are disposed along a tetragonal edge, but the present inventive concepts are not limited thereto and the arrangement of the conductive structures BP may be changed without limitation. The substrate 100 may be a compound semiconductor substrate or a semiconductor substrate including silicon, germanium, or silicon-germanium. For example, the substrate 100 may be a silicon substrate.

Referring to FIGS. 4 and 5A to 5E, a logic device may be disposed on the logic cell region LCR of the substrate 100 or on the logic cell LC of FIG. 3. The logic device may include channel patterns CH1 and CH2, source/drain patterns SD1 and SD2, and gate electrodes GE which will be discussed below. The logic cell region LCR may include a first active region AR1 and a second active region AR2. Each of the first and second active regions AR1 and AR2 may extend in the second direction D2. For example, the first active region AR1 may be a PMOSFET region, and the second active region AR2 may be an NMOSFET region. In this description, the first direction D1 and the second direction D2 may denote directions parallel to a bottom surface 100L of the substrate 100, and a third direction D3 may denote a direction perpendicular to the bottom surface 100L of the substrate 100.

The substrate 100 may include a first active pattern AP1 on the first active region AR1 and a second active pattern AP2 on the second active region AR2. The first active pattern AP1 and the second active pattern AP2 may be defined by a trench TR formed in the substrate 100. The first and second active patterns AP1 and AP2 may extend in the second direction D2.

A device isolation layer ST may be provided between the first and second active patterns AP1 and AP2. The device isolation layer ST may fill the trench TR. A bottom surface STL of the device isolation layer ST may be coplanar with bottom surfaces of the first and second active patterns AP1 and AP2. For example, the bottom surface STL of the device isolation layer ST may be located at the same level as or coplanar with that of the bottom surface 100L of the substrate 100. For example, the device isolation layer ST may include a silicon oxide layer. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (e.g., the third direction D3), which is perpendicular to the bottom surface 100L of the substrate 100.

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon, for example, monocrystalline silicon. Alternatively, the first, second, and third semiconductor patterns SP1, SP2, and SP3 may be stacked nano-sheets.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions of a first conductivity type (e.g., n-type). The first channel pattern CH1 may be positioned between the first source/drain patterns SD1 that are adjacent to each other in the second direction D2. For example, the stacked first, second, and third semiconductor patterns SP1, SP2, and SP3 of the first channel pattern CH1 may connect to each other the first source/drain patterns SD1 that are adjacent to each other in the second direction D2.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions of a second conductivity type (e.g., p-type). The second channel pattern CH2 may be positioned between the second source/drain patterns SD2 that are adjacent to each other in the second direction D2. For example, the stacked first, second, and third semiconductor patterns SP1, SP2, and SP3 of the second channel pattern CH2 may connect to each other the second source/drain patterns SD2 that are adjacent to each other in the second direction D2.

The first and second source/drain patterns SD1 and SD2 may be epitaxial patterns formed by a selective epitaxial growth (SEG) process. For example, a top surface of each of the first and second source/drain patterns SD1 and SD2 may be higher than that of the third semiconductor pattern SP3. For another example, a top surface of at least one of the first and second source/drain patterns SD1 and SD2 may be located at substantially the same level as that of a top surface of the third semiconductor pattern SP3.

The first source/drain patterns SD1 may include a semiconductor element (e.g., SiGe) whose lattice constant is greater than that of a semiconductor element of the substrate 100. Therefore, a pair of first source/drain patterns SD1 may provide a compressive stress to the first channel pattern CH1 therebetween. The second source/drain patterns SD2 may include the same semiconductor element (e.g., Si) as that of the substrate 100.

The first source/drain pattern SD1 may include impurities (e.g., boron, gallium, or indium) that cause the first source/drain pattern SD1 to have p-type conductivity. The first source/drain pattern SD1 may have an impurity concentration of about 1E18 atoms/cm³ to about 5E22 atoms/cm3.

Each of the second source/drain patterns SD2 may include silicon (Si). The second source/drain pattern SD2 may further include impurities (e.g., phosphorus, arsenic, or antimony) that cause the second source/drain pattern SD2 to have n-type conductivity. The second source/drain pattern SD2 may have an impurity concentration of about 1E18 atoms/cm³ to about 5E22 atoms/cm3.

Gate electrodes GE may be provided on the first and second channel patterns CH1 and CH2. Each of the gate electrodes GE may extend in the first direction D1, while running across the first and second channel patterns CH1 and CH2. Each of the gate electrodes GE may vertically overlap the first and second channel patterns CH1 and CH2. Components or layers described with reference to “overlap” in a particular direction (e.g., the vertical direction) may be at least partially obstructed by one another when viewed along a line extending in the particular direction or in a plane perpendicular to the particular direction. The gate electrodes GE may be spaced apart from each other in the second direction D2.

Each of the first and second gate electrodes GE may include a first inner electrode PO1 between the active pattern AP1 or AP2 and the first semiconductor pattern SP1, a second inner electrode PO2 between the first semiconductor pattern SP1 and the second semiconductor pattern SP2, a third inner electrode PO3 between the second semiconductor pattern SP2 and the third semiconductor pattern SP3, and an outer electrode PO4 on the third semiconductor pattern SP3.

Each of the gate electrodes GE may be provided on a top surface, a bottom surface, and opposite sidewalls of each of the first, second, and third semiconductor patterns SP1, SP2, and SP3. For example, a transistor according to the present inventive concepts may be a three-dimensional field effect transistor (e.g., MBCFET or GAAFET) in which the gate electrode GE three-dimensionally surrounds the first and second channel patterns CH1 and CH2.

On the second active region AR2, inner spacers ISP may be provided between the second source/drain patterns SD2 and the first, second, and third inner electrodes PO1, PO2, and PO3 of the gate electrodes GE. The first, second, and third inner electrodes PO1, PO2, and PO3 of the gate electrodes GE may be spaced apart from the second source/drain patterns SD2 across the inner spacers ISP. The inner spacer ISP may prevent a leakage current from the gate electrode GE.

A pair of gate spacers GS may be provided on opposite sidewalls of the outer electrode PO4 of each of the gate electrodes GE. The gate spacers GS may extend in the first direction D1 along the gate electrodes GE. For example, the gate spacers GS may include at least one selected from SiCN, SiCON, and SiN. Alternatively, the gate spacers GS may include a multi-layer formed of two or more of SiCN, SiCON, and SiN. The gate spacers GS may include, for example, a silicon-containing dielectric material. The gate spacers GS may serve as etch stop layers during the formation of upper active contacts AC which will be discussed below. The gate spacers GS may allow upper active contacts AC to form in a self-alignment manner.

Gate capping patterns GP may be correspondingly provided on the gate electrodes GE. The gate capping patterns GP may extend in the first direction D1 along the gate electrodes GE. The gate capping patterns GP may include a material having an etch selectivity with respect to first and second interlayer dielectric layers 110 and 120 which will be discussed below. For example, the gate capping patterns GP may include at least one selected from SiON, SiCN, SiCON, and SiN.

A gate dielectric layer GI may be provided between the gate electrodes GE and the first channel pattern CH1 and between the gate electrodes GE and the second channel pattern CH2. The gate dielectric layer GI may cover a top surface, a bottom surface, and opposite sidewalls of each of the first, second, and third semiconductor patterns SP1, SP2, and SP3. The gate dielectric layer GI may cover a top surface of the device isolation layer ST beneath the gate electrodes GE.

For example, the gate dielectric layer GI may include one or more of a silicon oxide layer, a silicon oxynitride layer, and a high-k dielectric layer. Alternatively, the gate dielectric layer GI may have a structure in which a silicon oxide layer and a high-k dielectric layer are stacked. The high-k dielectric layer may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

A first interlayer dielectric layer 110 may be provided on the substrate 100. The first interlayer dielectric layer 110 may cover the first and second source/drain patterns SD1 and SD2 and sidewalls of the gate spacers GS on the logic cell region LCR. The first interlayer dielectric layer 110 may have a top surface substantially coplanar with those of the gate capping patterns GP and those of the gate spacers GS, but the present inventive concepts are not limited thereto.

A second interlayer dielectric layer 120, a first upper dielectric layer 130, and a second upper dielectric layer 140 may be sequentially provided on the first interlayer dielectric layer 110. For example, the first and second interlayer dielectric layers 110 and 120 and the first and second upper dielectric layers 130 and 140 may include a silicon oxide layer.

The logic cell LC may have, on opposite sides thereof, a pair of separation structures DB that are opposite to each other in the second direction D2. The separation structures DB may extend in the first direction D1 parallel to the gate electrodes GE. The separation structures DB may penetrate the first interlayer dielectric layer 110 and the second interlayer dielectric layer 120 to extend into the first and second active patterns AP1 and AP2. The separation structures DB may penetrate portions of the first and second active patterns AP1 and AP2. The separation structures DB may electrically separate the logic cell LC from its adjacent another cell (e.g., a logic cell and a tap cell).

Upper active contacts AC may be provided to penetrate the first interlayer dielectric layer 110 and the second interlayer dielectric layer 120 to come into electrical connection with some of the first and second source/drain patterns SD1 and SD2. When viewed in plan view, each of the upper active contacts AC may have a bar shape that extends in the first direction D1. For example, each of the upper active contacts AC may include a conductive pattern and a barrier pattern that surrounds the conductive pattern. The barrier pattern may cover sidewalls and a bottom surface of the conductive pattern.

A metal-semiconductor compound layer SC may be provided between the upper active contact AC and the first source/drain pattern SD1 or between the upper active contact AC and the second source/drain pattern SD2. The upper active contact AC may be electrically connected through the metal-semiconductor compound layer SC to the first or second source/drain pattern SD1 or SD2. For example, the metal-semiconductor compound layer SC may include at least one selected from titanium silicide, tantalum silicide, tungsten silicide, nickel silicide, and cobalt silicide.

Gate contacts GC may be provided to penetrate the second interlayer dielectric layer 120 and the gate capping patterns GP to come into electrical connection with the gate electrodes GE. Each of the gate contacts GC may include a conductive pattern and a barrier pattern that surrounds the conductive pattern. For example, the gate contacts GC may have substantially the same structure as that of the upper active contacts AC. When viewed in plan view, the gate contacts GC may be disposed to correspondingly overlap the first active region AR1 and the second active region AR2.

A first upper metal layer M1 and a second upper metal layer M2 may be disposed on the second interlayer dielectric layer 120, but the present inventive concepts are not limited thereto. For example, a plurality of upper metal layers may be additionally stacked on the first and second upper metal layers M1 and M2. For convenience of description in this disclosure, the following will describe a semiconductor device that includes only the first upper metal layer M1 and the second upper metal layer M2. Moreover, in this disclosure, the second upper metal layer M2 may indicate an uppermost one of the plurality of upper metal layers M1 and M2.

The first and second upper metal layers M1 and M2 may include upper wiring line M1_V, M1_I, M2_V, and M2_I positioned on the logic cell region LCR of the substrate 100 and peripheral upper wiring lines M1_I′, M2_V′, and M2_I′ positioned on the peripheral region PR of the substrate 100. The upper wiring line M1_V, M1_I, M2_V, and M2_I may be electrically connected to the upper active contacts AC and the gate contacts GC, and the peripheral upper wiring lines M1_I′, M2_V′, and M2_I′ may be electrically connected to the conductive structure BP which will be discussed below.

For example, the first upper metal layer M1 may be provided on the first upper dielectric layer 130. The first upper metal layer M1 may include first upper wiring lines M1_I and M1_V provided on the logic cell region LCR and first peripheral upper wiring lines M1_I′ provided on the peripheral region PR. The first upper wiring lines M1_I and M1_V may include first upper line patterns M1_I and first upper vias M1_V. The first peripheral upper wiring lines M1_I′ may be called first peripheral upper line patterns M1_I′

The first upper line patterns M1_I may extend in parallel in the second direction D2, and may be spaced apart from each other in the first direction D1. The first upper vias M1_V may be disposed between the first upper line patterns M1_I and the upper active contact AC and between the first upper line patterns M1_I and the gate contact GC. For example, the first upper line patterns M1_I and their underlying first upper vias M1_V may be simultaneously formed in a dual damascene process.

The second upper metal layer M2 may be provided in the second upper dielectric layer 140. The second upper metal layer M2 may include second upper wiring lines M2_I and M2_V provided on the logic cell region LCR and second peripheral upper wiring lines M2_I′ and M2_V′ provided on the peripheral region PR. The second upper wiring lines M2_I and M2_V may include second upper line patterns M2_I and second upper vias M2_V. The second peripheral upper wiring lines M2_I′ and M2_V′ may include second peripheral upper line patterns M2_I′ and second peripheral upper vias M2_V′.

The second upper line patterns M2_I may extend in parallel in the first direction D1, and may be spaced apart from each other in the second direction D2. The second upper vias M2_V may be disposed between the second upper line patterns M2_I and the first upper line patterns M1_I. For example, the second upper line patterns M2_I and their underlying second upper vias M2_V may be simultaneously formed in a dual damascene process.

A power delivery network layer PDN may be provided on the bottom surface 100L of the substrate 100. The power delivery network layer PDN may include first, second, and third lower dielectric layers 160, 170, and 180 and first, second, and third lower metal layers LM1, LM2, and LM3 respectively provided in the first, second, and third lower dielectric layers 160, 170, and 180, but the present inventive concepts are not limited thereto. For example, the power delivery network layer PDN may include only the first and second lower metal layers LM1 and LM2, or may include an additional lower metal layer on a bottom surface of the third lower metal layer LM3. For convenience of description, the present disclosure explains an example in which the power delivery network layer PDN includes the first, second, and third lower metal layers LM1, LM2, and LM3. Moreover, in the present disclosure, the third lower metal layer LM3 may refer to a lowermost one of the lower metal layers LM1, LM2, and LM3.

The first, second, and third lower metal layers LM1, LM2, and LM3 may include lower wiring lines LM1_I, LM1_V, LM2_I, LM2_V, LM3_I, and LM3_V provided on a bottom surface of the logic cell region LCR and peripheral lower wiring lines LM1_I′, LM2_V′, LM2_I′, LM3_V′, and LM3_I′ provided on a bottom surface of the peripheral region PR. For example, the first lower metal layer LM1 provided in the first lower dielectric layer 160 may include first lower wiring lines LM1_I and LM1_V disposed on the bottom surface of the logic cell region LCR and first peripheral lower wiring lines LM1_I′ disposed on the bottom surface of the peripheral region PR. Likewise, the second and third lower metal layers LM2 and LM3 may include second and third lower wiring lines LM2_I, LM2_V, LM3_I, and LM3_V provided on the bottom surface of the logic cell region LCR and second and third peripheral lower wiring lines LM2_I′, LM2_V′, LM3_I′, and LM3_V′ provided on the bottom surface of the peripheral region PR.

The first lower vias LM1_V may be disposed between the first lower line patterns LM1_I and lower active contacts BAC which will be discussed below. For example, the first lower line patterns LM1_I and their underlying first lower vias LM1_V may be simultaneously formed in a dual damascene process.

The second lower vias LM2_V may lie between and electrically connect the first lower line patterns LM1_I and the second lower line patterns LM2_I. Likewise, the third lower vias LM3_V may lie between and electrically connect the second lower line patterns LM2_I and the third lower line patterns LM3_I. For example, the second lower line patterns LM2_I and their overlying second lower vias LM2_V may be simultaneously formed in a dual damascene process, and the third lower line patterns LM3_I and their overlying third lower vias LM3_V may be simultaneously formed in a dual damascene process.

The power delivery network layer PDN may include first and second power lines VSS and VDD that apply power voltages (e.g., power voltage and ground voltage). The first and second power lines VSS and VDD may parallel extend in the second direction D2, and may be provided in one or more of the first, second, and third lower dielectric layers 160, 170, and 180. For example, the first and second power lines VSS and VDD may be disposed in the third lower dielectric layer 180, and may be electrically connected to the first, second, and third lower wiring lines LM1_I, LM1_V, LM2_I, LM2_V, LM3_I, and LM3_V.

A third interlayer dielectric layer 150 may be provided between the substrate 100 and the power delivery network layer PDN. The third interlayer dielectric layer 150 may be in contact with the device isolation layer ST and the bottom surface 100L of the substrate 100. For example, the third interlayer dielectric layer 150 and the first and second lower dielectric layers 160 and 170 may include a silicon oxide layer.

Lower active contacts BAC may be provided to penetrate the third interlayer dielectric layer 150 and the substrate 100 and to extend to the first and second source/drain patterns SD1 and SD2. The lower active contacts BAC may be connected to the first and second source/drain patterns SD1 and SD2 that are not connected to the upper active contacts AC. For example, the lower active contacts BAC may be connected to the first lower vias LM1_V of the first lower metal layer LM1. For example, the lower active contacts BAC may have respective conductive pillar shapes that vertically extend and electrically connect the first and second power lines VSS and VDD to the first and second source/drain patterns SD1 and SD2. A source voltage or a drain voltage may be applied through the lower active contacts BAC to the first and second source/drain patterns SD1 and SD2.

Referring to FIGS. 4 and 5E, the first and second interlayer dielectric layers 110 and 120 may cover a top surface 100U of the substrate 100 on the peripheral region PR. The first and second upper dielectric layers 130 and 140 may be provided on the first and second interlayer dielectric layers 110 and 120. The third interlayer dielectric layer 150 may be provided on the bottom surface 100L of the substrate 100 on the peripheral region PR. The first, second, and third lower dielectric layers 160, 170, and 180 may be disposed on a bottom surface of the third interlayer dielectric layer 150.

The conductive structures BP may be provided to penetrate the peripheral region PR. The conductive structure BP may penetrate the peripheral region PR of the substrate 100 to vertically extend onto or beyond the top and bottom surfaces 100U and 100L of the substrate 100 in the vertical direction (e.g., D3). The conductive structure BP may penetrate the first and second interlayer dielectric layers 110 and 120, and may also penetrate at least a portion of each of the first upper dielectric layer 130 and the first lower dielectric layer 160. That is, the conductive structure BP may be a unitary member that extends through the substrate 100 and beyond the top and bottom surfaces 100U and 100L, and extends into one or more dielectric layers 110, 120, 130 thereabove and/or 150, 160 therebelow.

The conductive structure BP may be connected to the first and second peripheral upper wiring lines M1_I′, M2_I′, and M2_V′ and the first, second, and third peripheral lower wiring lines LM1_I′, LM2_I′, LM2_V′, LM3_I′, and LM3_V′. For example, the first and second peripheral upper wiring lines M1_I′, M2_I′, and M2_V′ may be connected to a top surface of each of the conductive structures BP, and the first, second, and third peripheral lower wiring lines LM1_I′, LM2_I′, LM2_V′, LM3_I′, and LM3_V′ may be connected to a bottom surface of each of the conductive structures BP. When viewed in plan view, the conductive structure BP may overlap corresponding first and second peripheral upper wiring lines M1_I′, M2_I′, and M2_V′ and corresponding first, second, and third peripheral lower wiring lines LM1_I′, LM2_I′, LM2_V′, LM3_I′, and LM3_V′

Alternatively, although not shown, the conductive structure BP may extend along a vertical direction to penetrate a portion of the second upper dielectric layer 140 and a portion of the second lower dielectric layer 170, and thus, neither the first peripheral upper wiring lines M1_I′ nor the first peripheral lower wiring lines LM1_I′ may be present in some embodiments.

The conductive structure BP may have a circular shape when viewed in plan view, but the present inventive concepts are not limited thereto. For example, a width W1 in the first direction D1 of the conductive structure BP may have a value ranging from about 400 nm to about 600 nm. When the conductive structure BP has a circular shape when viewed in plan view, the width W1 in the first direction D1 of the conductive structure BP may refer to a diameter of the conductive structure BP.

The conductive structure BP may include, for example, at least one metal selected from copper, aluminum, tungsten, molybdenum, and cobalt. In addition, the conductive structure BP may further include a metal nitride layer (not shown) that covers a sidewall thereof. The metal nitride layer may include, for example, at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

Each of the first peripheral upper line patterns M1_I′ may cover the top surface of the conductive structure BP, and may have a direct connection with the conductive structure BP. The first peripheral upper line patterns M1_I′ may each have, for example, a square shape when viewed in plan view. A width W1 in the first direction D1 of each of the first peripheral upper line patterns M1_I′ may be greater than the width W1 in the first direction D1 of the conductive structure BP. The width W2 in the first direction D1 of the first peripheral upper line pattern M1_I′ may have a value ranging from about 500 nm to about 700 nm.

The second peripheral upper line patterns M2_I′ may be correspondingly disposed on the first peripheral upper line patterns M1_I′. The second peripheral upper line patterns M2_I′ may each have, for example, a square shape when viewed in plan view. In addition, when viewed in plan view, the second peripheral upper line patterns M2_I′ may correspondingly overlap the first peripheral upper line patterns M1_I′. The second peripheral upper vias M2_V′ may electrically connect the first peripheral upper line patterns M1_I′ to the second peripheral upper line patterns M2_I′. For example, a plurality of second peripheral upper vias M2_V′ may be disposed on each of the first peripheral upper line patterns M1_I′.

Each of the first peripheral lower line patterns LM1_I′ may cover the bottom surface of the conductive structure BP, and may have a direct connection with the conductive structure BP. For example, the first peripheral lower line patterns LM1_I′ may each have a square shape when viewed in plan view. A width W3 in the first direction D1 of each of the first peripheral lower line patterns LM1_I′ may be greater than the width W1 in the first direction D1 of the conductive structure BP. The width W3 in the first direction D1 of the first peripheral lower line pattern LM1_I′ may have a value ranging from about 500 nm to about 700 nm.

The second and third peripheral lower line patterns LM2_I′ and LM3_I′ may be sequentially disposed below the first peripheral lower line patterns LM1_I′. For example, the second and third peripheral lower line patterns LM2_I′ and LM2_I′ may each have a square shape when viewed in plan view. In addition, when viewed in plan view, the second and third peripheral lower line patterns LM2_I′ and LM3_I′ may correspondingly overlap the first peripheral lower line patterns LM1_I′. The second and third peripheral lower vias LM2_V′ and LM3_V′ may be correspondingly disposed between the first peripheral lower line patterns LM1_I′ and the second peripheral lower line patterns LM2_I′ and between the second peripheral lower line patterns LM2_I′ and the third peripheral lower line patterns LM3_I′.

FIG. 6 illustrates a cross-sectional views showing a semiconductor device according to some embodiments of the present inventive concepts, which corresponds to FIG. 5E. In the embodiment that follows, a detailed description of technical features repetitive to those discussed above with reference to FIGS. 4 and 5A, 5B, 5C, 5D, and 5E will be omitted, and differences thereof will be discussed in detail.

Referring to FIG. 6, first external connection terminals 210 may be disposed on the first and second peripheral upper wiring lines M1_I′, M2_I′, and M2_V′. For example, the first external connection terminal 210 may be directly connected to an uppermost one (e.g., the second peripheral upper line pattern M2_I′) of the first and second peripheral upper wiring lines M1_I′, M2_I′, and M2_V′.

Second external connection terminals 220 may be disposed below the first, second, and third peripheral lower wiring lines LM1_I′, LM2_I′, LM2_V′, LM3_I′, and LM3_V′. For example, the second external connection terminal 220 may be directly connected to a lowermost one (e.g., the third peripheral lower line pattern LM3_I′) of the first, second, and third peripheral lower wiring lines LM1_I′, LM2_I′, LM2_V′, LM3_I′, and LM3_V′.

The first external connection terminals 210 and the second external connection terminals 220 may electrically and physically connect a semiconductor device to external devices coupled to upper and lower portions of the semiconductor device. The first external connection terminals 210 and the second external connection terminals 220 may be, for example, solder balls or solder bumps.

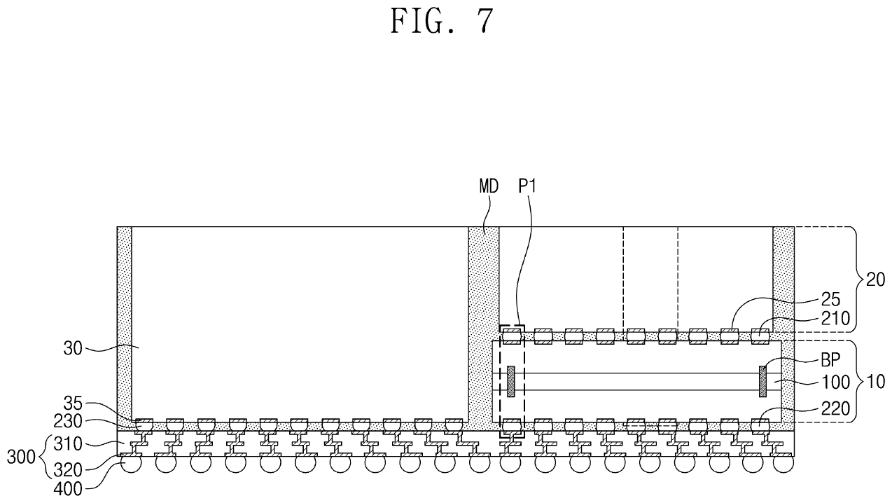

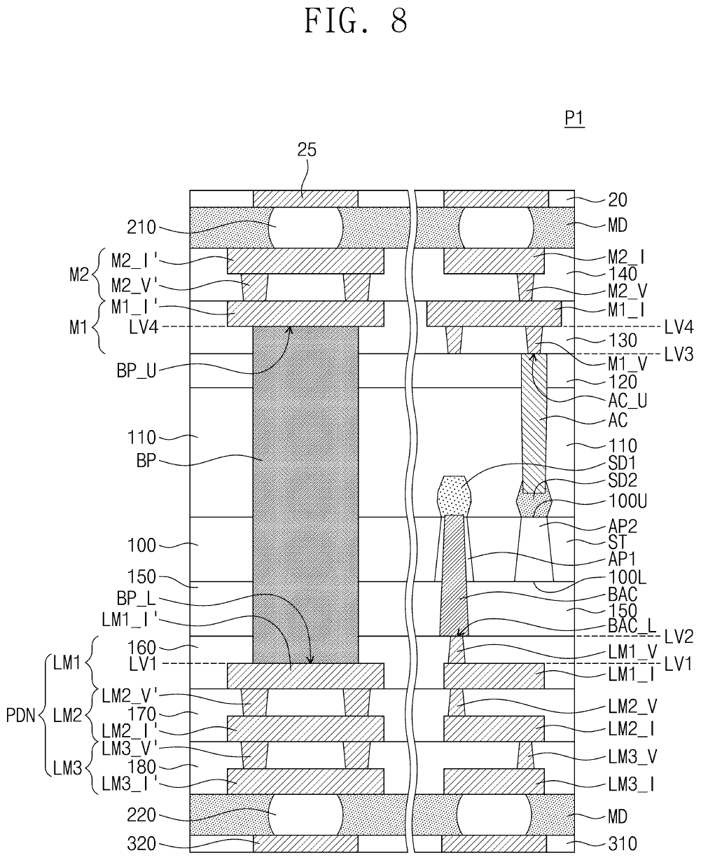

FIG. 7 illustrates a cross-sectional view showing a semiconductor device according to some embodiments of the present inventive concepts. FIG. 8 illustrates an enlarged view showing section P1 of FIG. 7. In the embodiment that follows, a detailed description of technical features repetitive to those discussed above with reference to FIGS. 4 and 5A, 5B, 5C, 5D, and 5E will be omitted, and differences thereof will be discussed in detail.

Referring to FIG. 7, a redistribution substrate 300 may be provided. The redistribution substrate 300 may be manufactured by a redistribution process and may include a redistribution dielectric layer 310 and a redistribution conductive pattern 320. For example, the redistribution dielectric layer 310 may include a silicon-based dielectric material, and the redistribution conductive pattern 320 may include at least one selected from copper and titanium.

First and second semiconductor chips 10 and 20 may be vertically stacked on the redistribution substrate 300. The redistribution substrate 300 may further be provided thereon with a third semiconductor chip 30 horizontally spaced apart from the first and second semiconductor chips 10 and 20. The first semiconductor chip 10 may be the semiconductor device discussed above in FIGS. 3 to 5E. The second and third semiconductor chips 20 and 30 may be, for example, logic chips, memory chips, or capacitors.

Second external connection terminals 220 may be disposed between the redistribution substrate 300 and the first semiconductor chip 10, and first external connection terminals 210 may be disposed between the first semiconductor chip 10 and the second semiconductor chip 20. Third external connection terminals 230 may be disposed between the redistribution substrate 300 and the third semiconductor chip 30. The third external connection terminal 230 may electrically connect a chip pad 35 of the third semiconductor chip 30 to the redistribution conductive pattern 320. The first and second external connection terminals 210 and 220 may electrically connect the first and second semiconductor chips 10 and 20 to the redistribution substrate 300.

Referring to FIGS. 7 and 8, a bottom surface BP_L of the conductive structure BP may be located at a lower level than that of a top surface of the first lower dielectric layer 160. For example, the bottom surface BP_L of the conductive structure BP may be located at a first level LV1 between top and bottom surfaces of the first lower dielectric layer 160, and may be coplanar with a bottom surface of the first lower via LM1_V. The first level LV1 may be vertically lower than a second level LV2 of a bottom surface BAC_L of the lower active contact BAC connected to the first source/drain pattern SD1. The term “level” may be used herein to refer to a distance from or relative to a reference element, component, layer, or surface thereof.

A top surface BP_U of the conductive structure BP may be located at a higher level than that of a bottom surface of the first upper dielectric layer 130. For example, the top surface BP_U of the conductive structure BP may be located at a fourth level LV4 between top and bottom surfaces of the first upper dielectric layer 130, and may be coplanar with a top surface of the first upper via M1_V. The fourth level LV4 may be vertically higher than a third level LV3 of a top surface AC_U of the upper active contact AC connected to the second source/drain pattern SD2.

According to some embodiments of the present inventive concepts, the first and second peripheral upper wiring lines M1_I′, M2_I′, and M2_V′, the conductive structure BP, and the first, second, and third peripheral lower wiring lines LM1_I′, LM2_I′, LM2_V′, LM3_I′, and LM3_V′, which are vertically stacked, may electrically connect top and bottom ends (i.e., opposing surfaces) of the first semiconductor chip 10. For example, the first and second peripheral upper wiring lines M1_I′, M2_I′, and M2_V′, the conductive structure BP, and the first, second, and third peripheral lower wiring lines LM1_I′, LM2_I′, LM2_V′, LM3_I′, and LM3_V′, which are vertically connected to each other, may serve as through vias (TSV). That is, the conductive structure BP, the upper wiring line(s), and the lower wiring line(s) collectively function as a TSV that extends between the opposing top and bottom surfaces of a semiconductor chip 10. In such a configuration, even though no through via is separately formed to vertically penetrate the first semiconductor chip 10, the second semiconductor chip 20 may receive electrical signals from the redistribution substrate 300 through the first and second peripheral upper wiring lines M1_I′, M2_I′, and M2_V′, the conductive structure BP, and the first, second, and third peripheral lower wiring lines LM1_I′, LM2_I′, LM2_V′, LM3_I′, and LM3_V′.

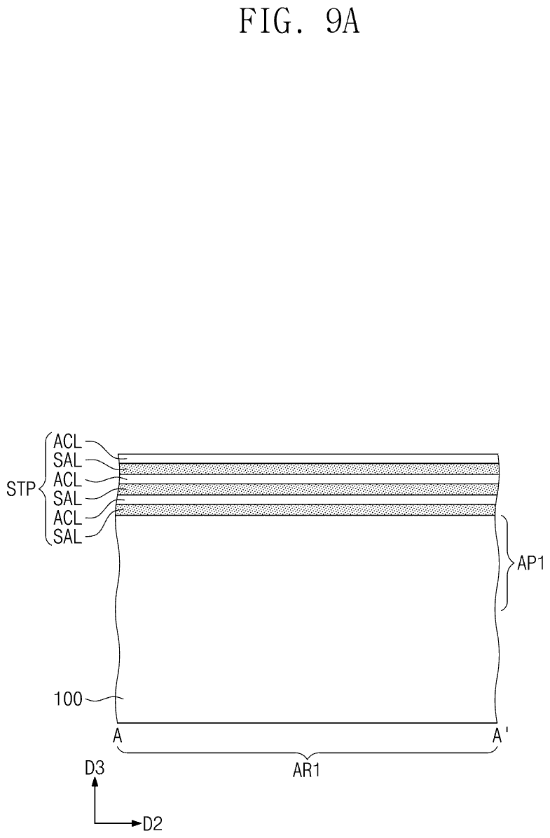

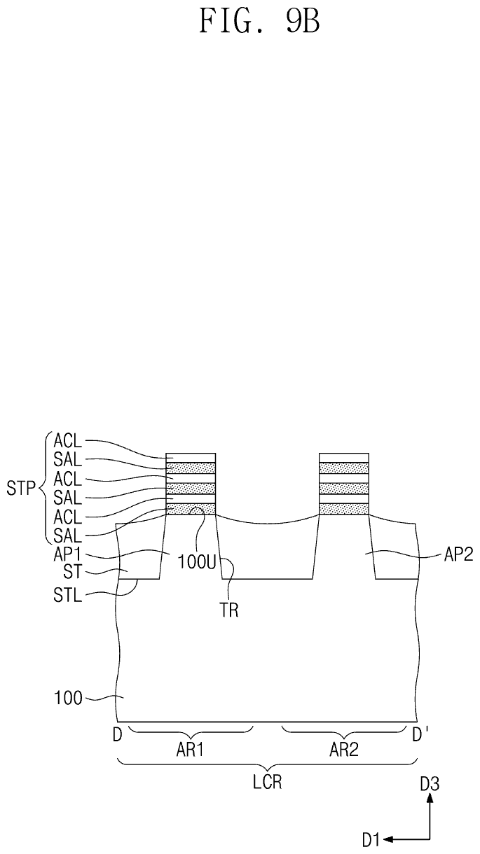

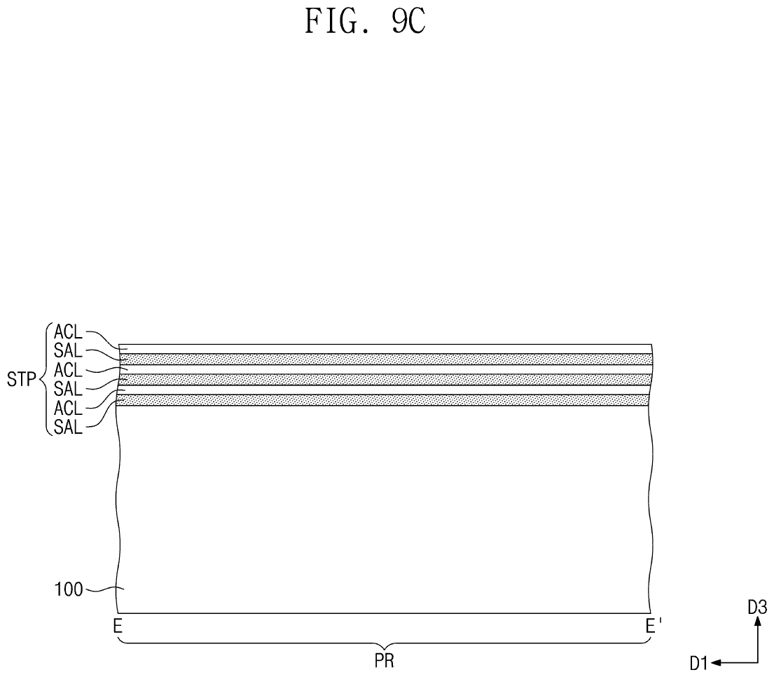

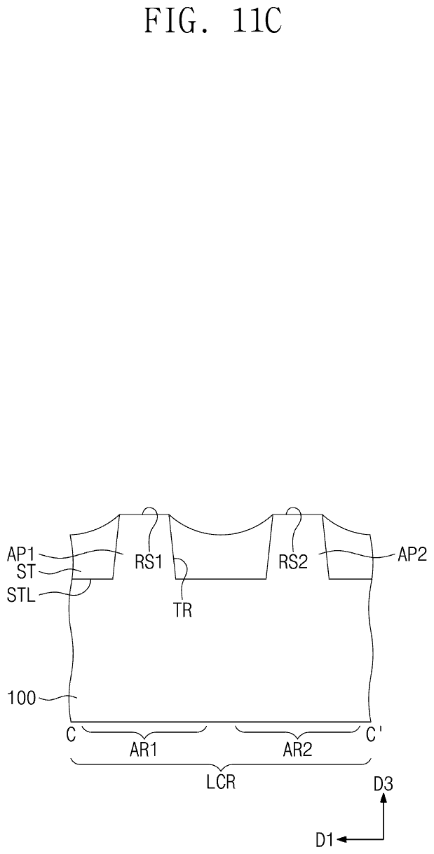

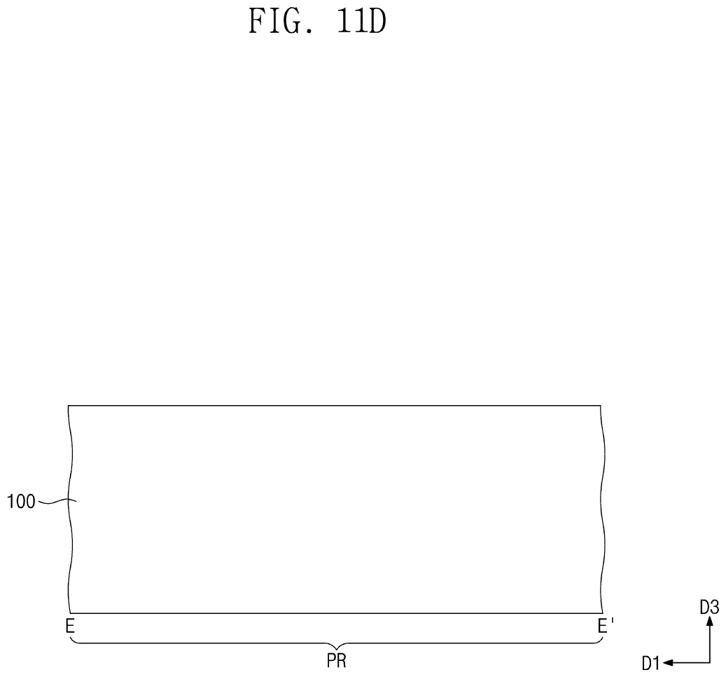

FIGS. 9A, 9B, 9C, 10A, 10B, 11A, 11B, 11C, 11D, 12A, 12B, 12C, 13A, 13B, 13C, 13D, 14A, 14B, 14C, 14D, 14E, 15A, 15B, 15C, 15D, 15E, 16A, 16B, 16D, 16E, 17A 17B, 17C, 17D, and 17E illustrate diagrams showing a method of fabricating a semiconductor device according to some embodiments of the present inventive concepts. In detail, FIGS. 9A, 10A, 11A, 12A, 13A, 14A, 15A, 16A, and 17A illustrate cross-sectional views that correspond to FIG. 5A, and FIGS. 11B, 12B, 13B, 14B, 15B, 16B, and 17B illustrate cross-sectional views that correspond to FIG. 5B. FIGS. 11C, 12C, 14C, 15C, 16C, and 17C illustrate cross-sectional views that correspond to FIG. 5C, and FIGS. 9B, 10B, 13C, 14D, 15D, 16D, and 17D illustrate cross-sectional views that correspond to FIG. 5D. FIGS. 9C, 11D, 13D, 14E, 15E, 16E, and 17E illustrate cross-sectional views that correspond to FIG. 5E.

Referring to FIGS. 3 and 9A, 9B, and 9C, a substrate 100 may be provided which includes a logic cell region LCR and a peripheral region PR that surrounds the logic cell region LCR. The logic cell region LCR may include first and second active regions AR1 and AR2. Active layers ACL and sacrificial layers SAL may be formed alternately stacked on a top surface 100U of the substrate 100. The active layers ACL may include one of silicon (Si), germanium (Ge), and silicon-germanium (SiGe), and the sacrificial layers SAL may include another of silicon (Si), germanium (Ge), or silicon-germanium (SiGe).

The sacrificial layers SAL may include a material having an etch selectivity with respect to the active layers ACL. For example, the active layers ACL may include silicon (Si), and the sacrificial layers SAL may include silicon-germanium (SiGe). Each of the sacrificial layers SAL may have a germanium concentration of about 10 at % to about 30 at %.

A mask pattern may be formed on the first and second active regions AR1 and AR2 of the logic cell region LCR. The mask pattern may have bar shapes that are spaced apart from each other in a first direction D1 and extend in a second direction D2 on the logic cell region LCR, and may cover the sacrificial layers SAL and the active layers ACL on the peripheral region PR. A patterning process using the mask pattern may be performed to form trenches TR that define a first active pattern AP1 and a second active pattern AP2. On the logic cell region LCR, the trenches TR may extend in the second direction D2 and may be spaced apart from each other. The first active pattern AP1 may be formed on the first active region AR1. The second active pattern AP2 may be formed on the second active region AR2. When viewed in plan view, the first and second active patterns AP1 and AP2 may have respective linear shapes that extend in parallel in the second direction D2.

Stack patterns STP may be formed on the first and second active patterns AP1 and AP2. Each of the stack patterns STP may include the active layers ACL and the sacrificial layers SAL that are alternately stacked. For example, the stack patterns STP may be formed by an etching process for forming the first and second active patterns AP1 and AP2.

Thereafter, a device isolation layer ST may be formed to fill the trench TR. For example, a dielectric layer may be formed on the top surface 100U of the substrate 100 to thereby cover the first and second active patterns AP1 and AP2 and the stack patterns STP, and the dielectric layer may be recessed to form the device isolation layer ST. The stack patterns STP may be exposed upwardly from the device isolation layer ST. For example, the stack patterns STP may vertically protrude upwards from the device isolation layer ST. The term “exposed,” may be used to describe relationships between elements and/or certain intermediate processes in fabricating a completed semiconductor device, but may not necessarily require exposure of the particular region, layer, structure or other element in the context of the completed device. The device isolation layer ST may include a dielectric material, such as a silicon oxide layer.

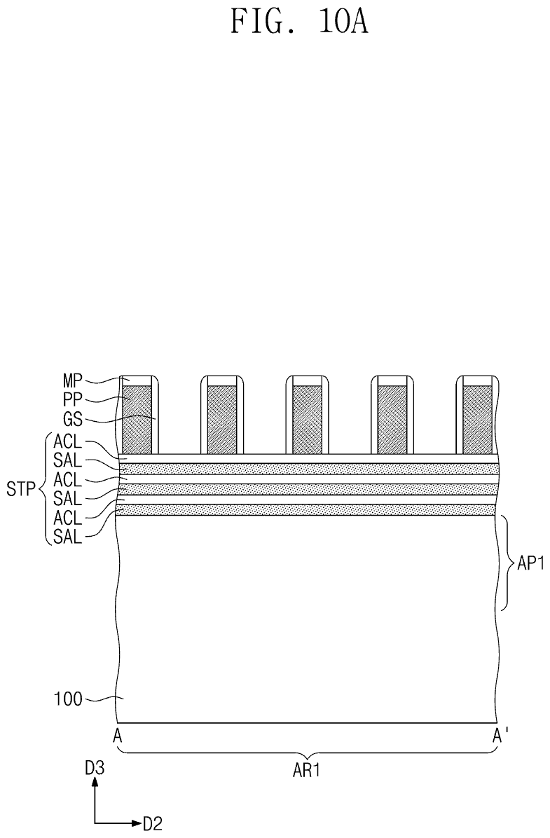

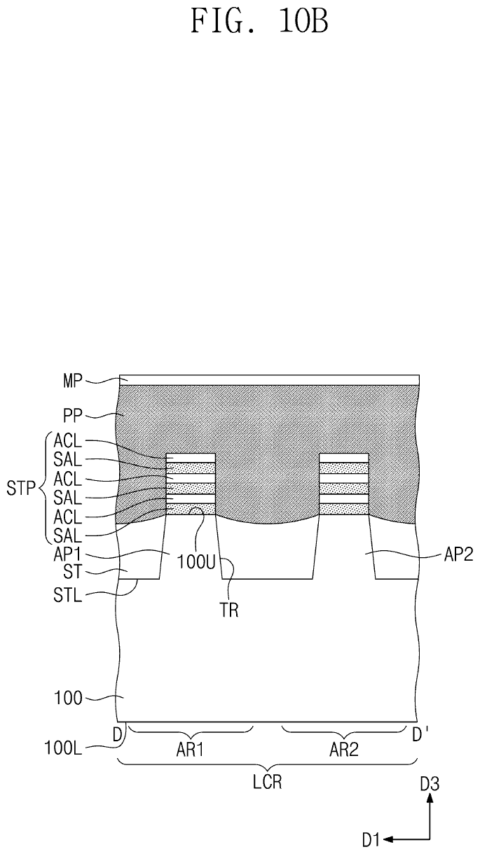

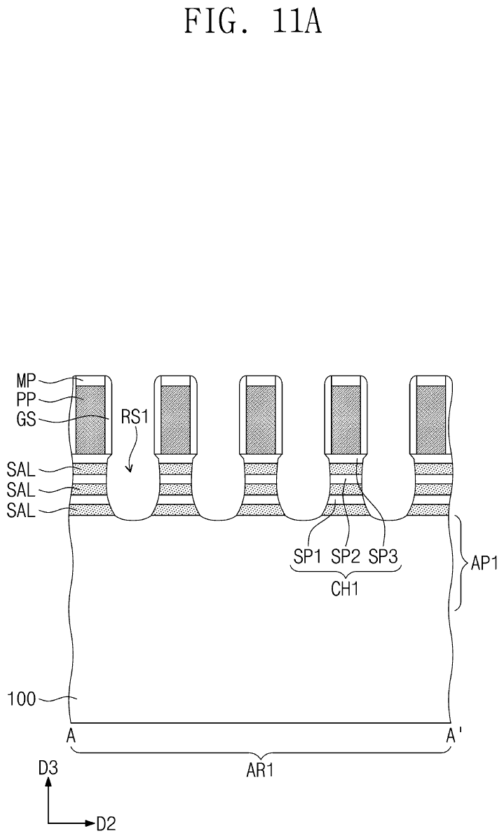

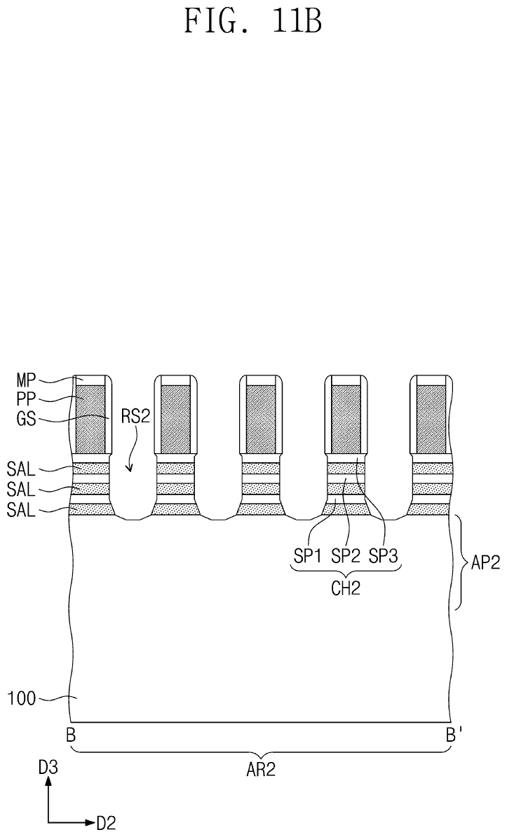

Referring to FIGS. 10A and 10B, sacrificial patterns PP may be formed on the logic cell region LCR of the substrate 100, thereby running across the stack patterns STP. The sacrificial patterns PP may be formed to have their linear or bar shapes that extend in the first direction D1. The sacrificial patterns PP may be spaced apart from each other in the second direction D2. The sacrificial patterns PP may not be formed on the peripheral region PR of the substrate 100.

For example, the formation of the sacrificial patterns PP may include forming a sacrificial layer on the logic cell region LCR of the substrate 100, forming hardmask patterns MP on the sacrificial layer, and using the hardmask patterns MP as an etching mask to pattern the sacrificial layer. The sacrificial layer may include polysilicon.

A pair of gate spacers GS may be formed on opposite sidewalls of each of the sacrificial patterns PP. The formation of the gate spacers GS may include conformally forming a gate spacer layer on the logic cell region LCR of the substrate 100 and anisotropically etching the gate spacer layer. The gate spacer layer may include at least one selected from SiCN, SiCON, and SiN. Alternatively, the gate spacer layer may be a multi-layer including at least two selected from SiCN, SiCON, and SiN.

Referring to FIGS. 11A, 11B, 11C, and 11D, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may further be recessed on opposite sides of each of the first and second active patterns AP1 and AP2 (see FIG. 11C).

For example, on the logic cell region LCR of the substrate 100, the hardmask patterns MP and the gate spacers GS may be used as an etching mask to etch the stack pattern STP on the first active pattern AP1, therefore forming the first recesses RS1. The first recess RS1 may be formed between a pair of neighboring sacrificial patterns PP. The second recesses RS2 in the stack pattern STP on the second active pattern AP2 may be formed by the same method used for the formation of the first recesses RS1. During the formation of the first and second recesses RS1 and RS2, the stack pattern STP may be removed on the peripheral region PR of the substrate 100.

After the formation of the first recesses RS1, the active layers (see ACL of FIG. 10A) sequentially stacked between neighboring first recesses RS1 may be called first, second, and third semiconductor patterns SP1, SP2, and SP3 in sequence. Likewise, after the formation of the second recesses RS2, active layers (not shown) sequentially stacked between neighboring second recesses RS2 may be called first, second, and third semiconductor patterns SP1, SP2, and SP3 in sequence. A first channel pattern CH1 may be constituted by the first, second, and third semiconductor patterns SP1, SP2, and SP3 between neighboring first recesses RS1. A second channel pattern CH2 may be constituted by the first, second, and third semiconductor patterns SP1, SP2, and SP3 between neighboring second recesses RS2.

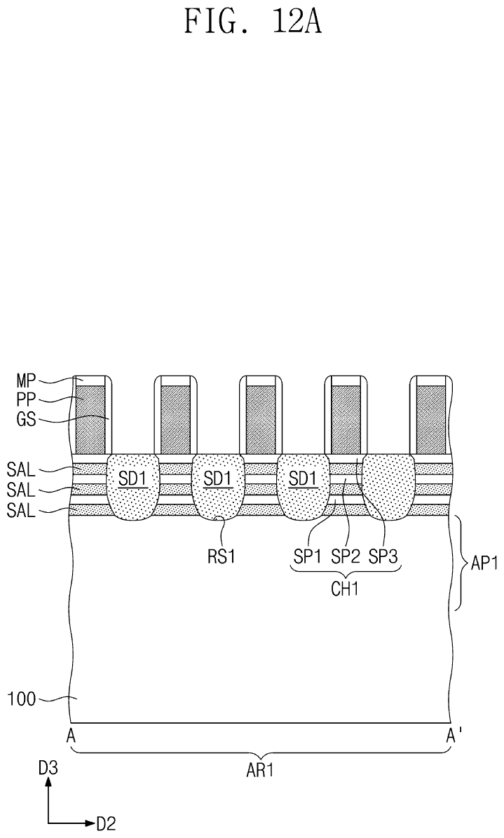

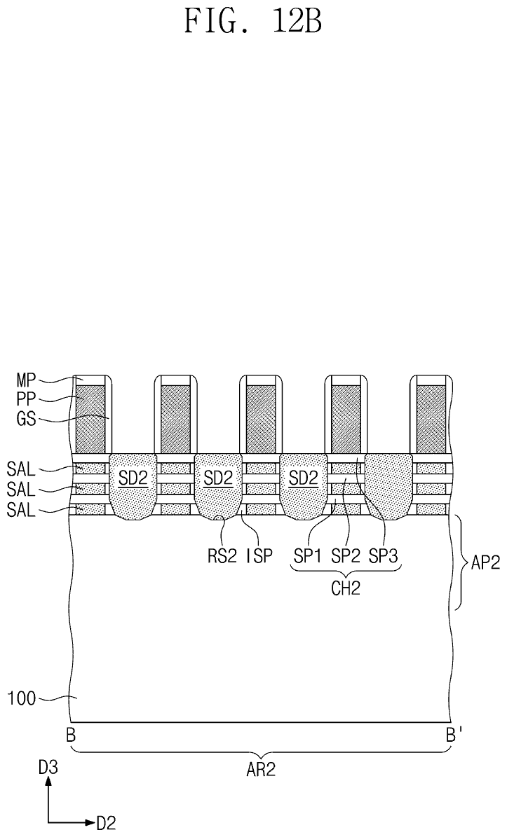

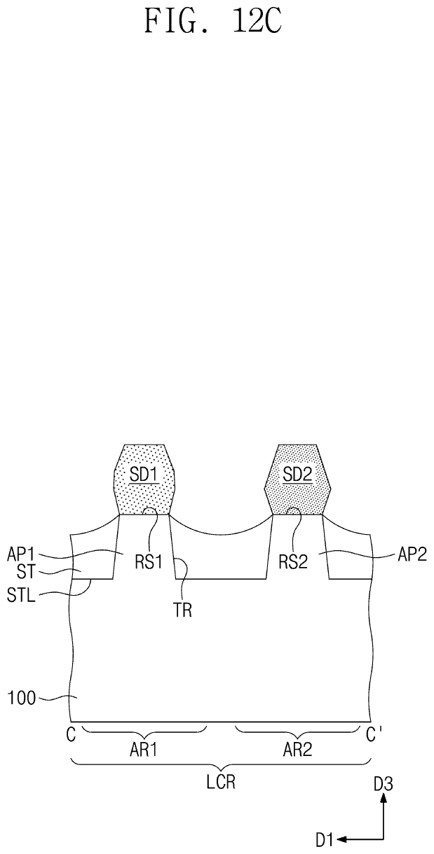

Referring to FIGS. 12A, 12B, and 12C, first source/drain patterns SD1 may be correspondingly formed in the first recesses RS1. For example, the formation of the first source/drain patterns SD1 may include performing a selective epitaxial growth (SEG) process in which an inner wall of the first recess RS1 is used as a seed layer. The first source/drain patterns SD1 may be grown from seeds, or the first, second, and third semiconductor patterns SP1, SP2, and SP3 and the substrate 100 that are exposed by the first recess RS1. For example, the SEG process may include chemical vapor deposition (CVD) or molecular beam epitaxy (MBE).

The first source/drain patterns SD1 may include a semiconductor element (e.g., SiGe) whose lattice constant is greater than that of a semiconductor element of the substrate 100. During the formation of the first source/drain pattern SD1, impurities (e.g., boron, gallium, or indium) may be in-situ implanted to allow the first source/drain pattern SD1 to have p-type conductivity. Alternatively, after the formation of the first source/drain pattern SD1, impurities may be implanted into the first source/drain pattern SD1.

Second source/drain patterns SD2 may be correspondingly formed in the second recesses RS2. For example, the formation of the second source/drain pattern SD2 may include performing a selective epitaxial growth (SEG) process in which an inner wall of the second recess RS2 is used as a seed layer. For example, the second source/drain pattern SD2 may include the same semiconductor element (e.g., Si) as that of the substrate 100.

During the formation of the second source/drain pattern SD2, impurities (e.g., phosphorus, arsenic, or antimony) may be in-situ implanted to allow the second source/drain pattern SD2 to have n-type conductivity. Alternatively, after the formation of the second source/drain pattern SD2, impurities may be implanted into the second source/drain pattern SD2.

In an embodiment of the present inventive concepts, before the formation of the second source/drain pattern SD2, a portion of the sacrificial layer SAL exposed through the second recess RS2 may be replaced with a dielectric material to form an inner spacer ISP. As a result, inner spacers ISP may be correspondingly formed between the second source/drain pattern SD2 and the sacrificial layers SAL.

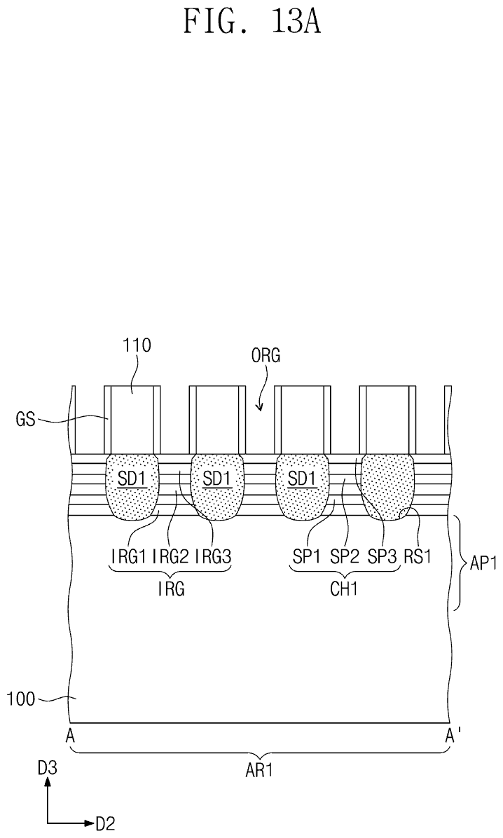

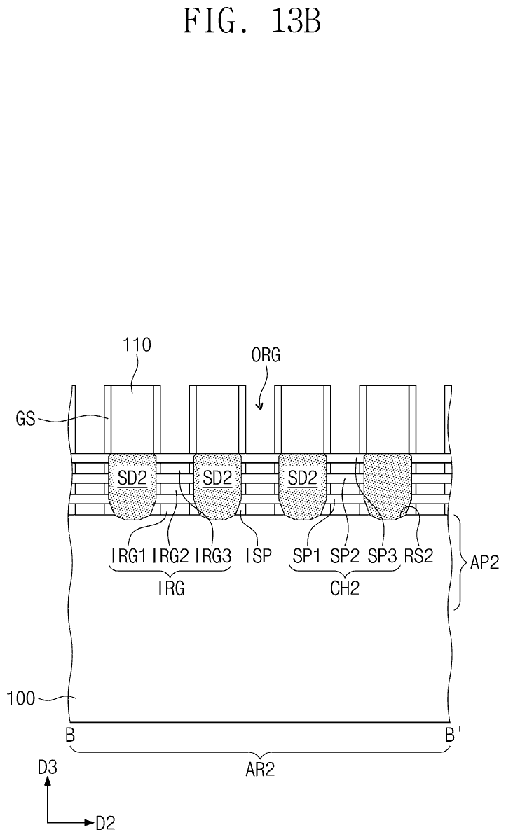

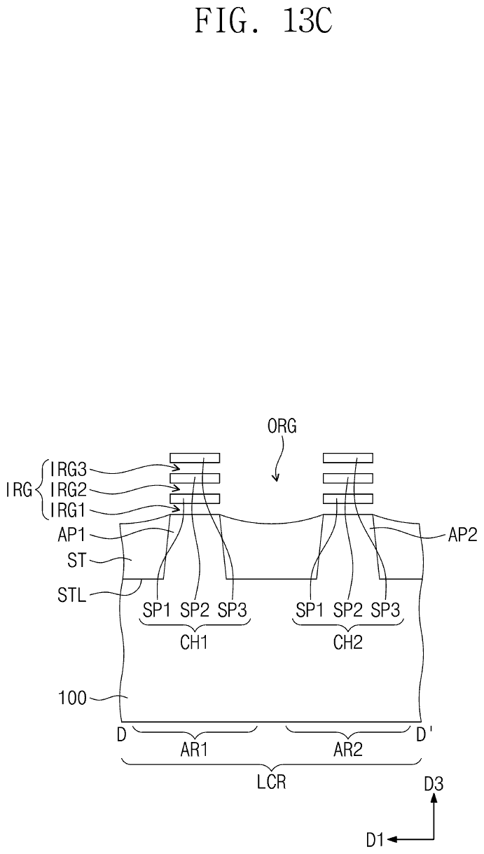

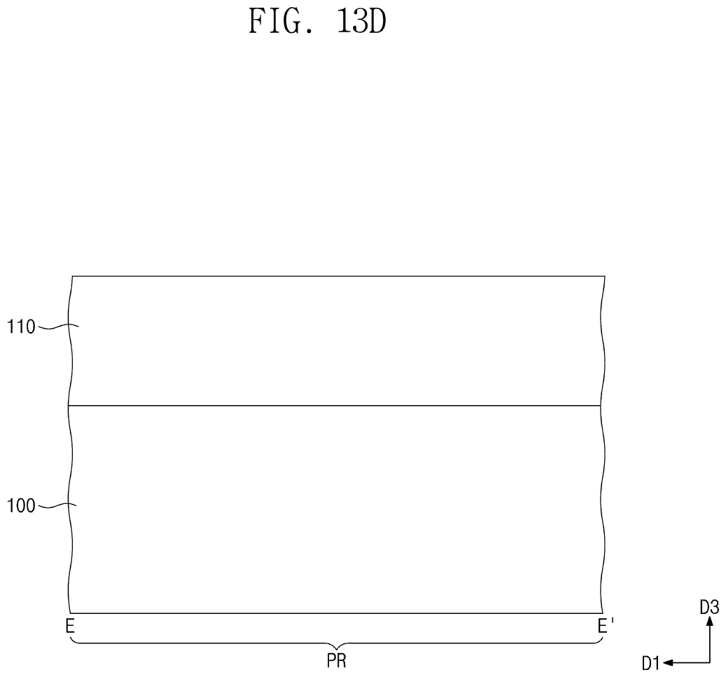

Referring to FIGS. 13A, 13B, 13C, and 13D, a first interlayer dielectric layer 110 may be formed to cover the logic cell region LCR and the peripheral region PR of the substrate 100. On the logic cell region LCR, the first interlayer dielectric layer 110 may cover the first and second source/drain patterns SD1 and SD2, the hardmask patterns (see MP of FIG. 12A), and the gate spacers GS. For example, the first interlayer dielectric layer 110 may include a silicon oxide layer.

The first interlayer dielectric layer 110 may be planarized until top surfaces of the sacrificial patterns (see PP of FIG. 12A) are exposed. An etch-back or chemical mechanical polishing (CMP) process may be used to planarize the first interlayer dielectric layer 110. During the planarization process, the hardmask patterns (see MP of FIG. 12A) may be all removed. In conclusion, the first interlayer dielectric layer 110 may have a top surface coplanar with those of the sacrificial patterns (see PP of FIG. 12A) and those of the gate spacers GS.

After that, the exposed sacrificial patterns (see PP of FIG. 12A) may be selectively removed. The removal of the sacrificial patterns (see PP of FIG. 12A) may form an outer region ORG that exposes the first and second channel patterns CH1 and CH2 (see FIG. 13C). The removal of the sacrificial patterns PP may include performing a wet etching process using an etchant that selectively etches polysilicon.

The sacrificial layers (see SAL of FIG. 12A) exposed through the outer region ORG may be selectively removed to form inner regions IRG (see FIG. 13C). For example, an etching process that selectively etches the sacrificial layers SAL may be performed such that only the sacrificial layers SAL may be removed while leaving the first, second, and third semiconductor patterns SP1, SP2, and SP3. The etching process may have a high etch rate for silicon-germanium having a relatively high germanium concentration.

Referring back to FIG. 13C, as the sacrificial layers (see SAL of FIG. 10B) are selectively removed, only the stacked first, second, and third semiconductor patterns SP1, SP2, and SP3 may remain on each of the first and second active patterns AP1 and AP2. The removal of the sacrificial layers (see SAL of FIG. 10B) may form first, second, and third inner regions IRG1, IRG3, and IRG3.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

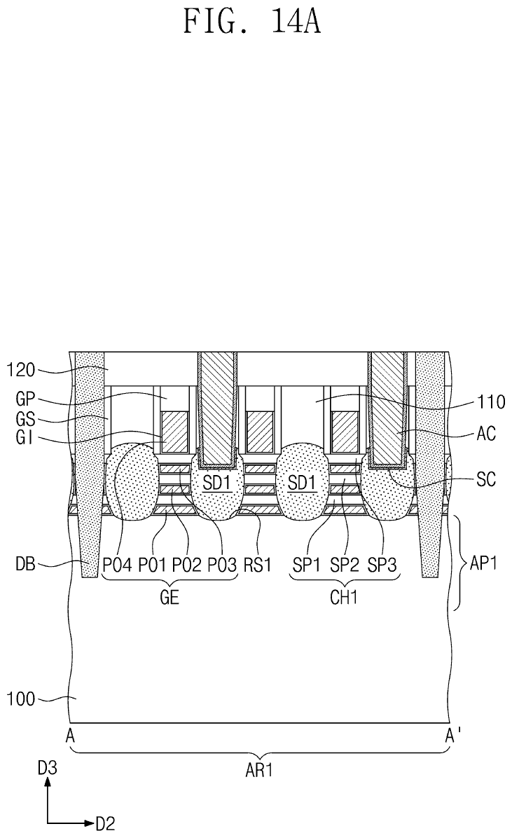

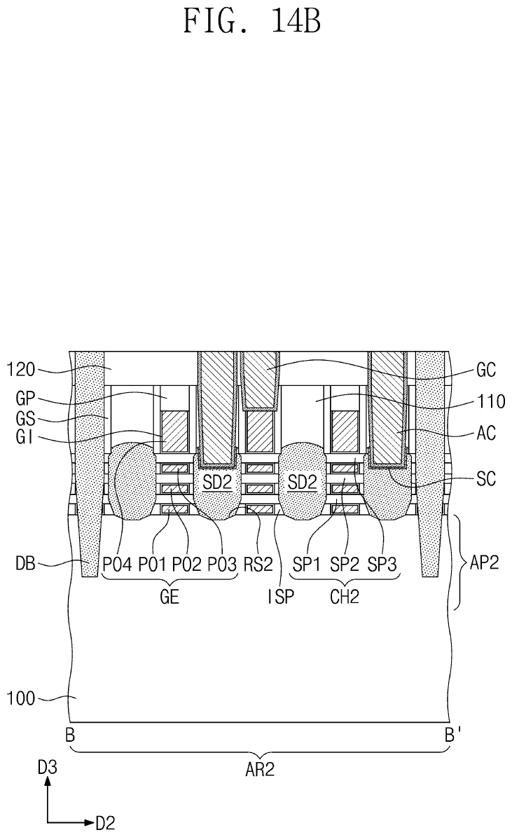

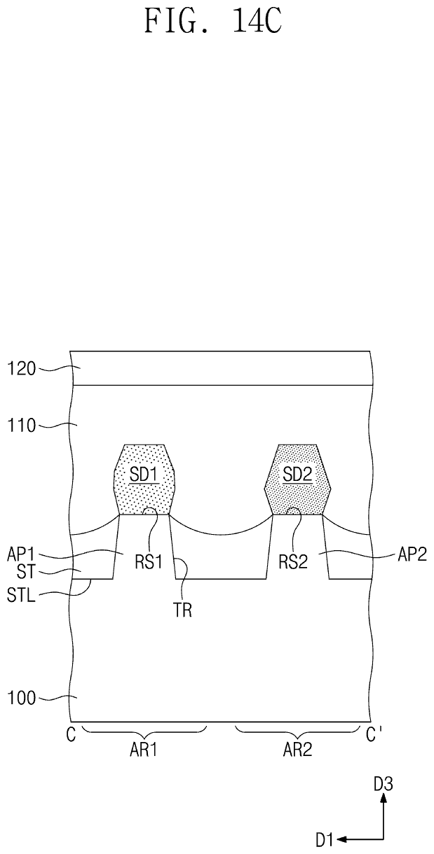

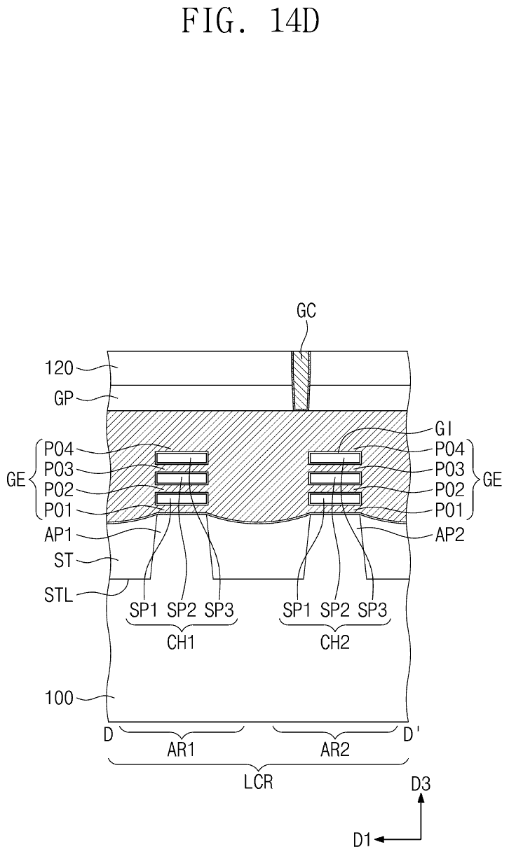

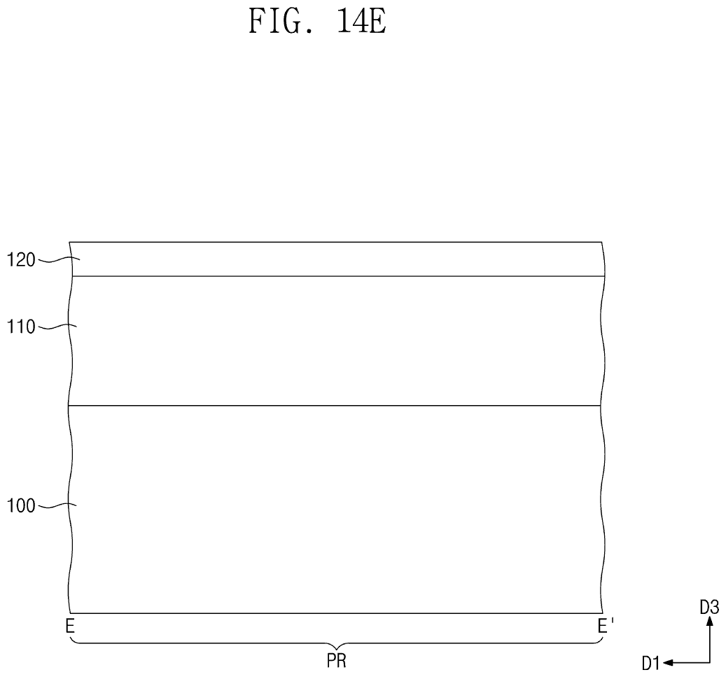

Referring to FIGS. 14A, 14B, 14C, 14D, and 14E, a gate dielectric layer GI may be conformally formed on the exposed first, second, and third semiconductor patterns SP1, SP2, and SP3. A gate electrode GE may be formed on the gate dielectric layer GI. The gate electrode GE may include first, second, and third inner electrodes PO1, PO2, and PO3 that are respectively formed in the first, second, and third inner regions IRG1, IRG2, and IRG3, and may also include an outer electrode PO4 formed in the outer region ORG. A gate capping pattern GP may be formed on the gate electrode GE.

A second interlayer dielectric layer 120 may be formed on the logic cell region LCR and the peripheral region PR of the substrate 100. The second interlayer dielectric layer 120 may cover the gate capping pattern GP and the first interlayer dielectric layer 110. For example, the second interlayer dielectric layer 120 may include a silicon oxide layer.

Upper active contacts AC may be formed to penetrate the second interlayer dielectric layer 120 and the first interlayer dielectric layer 110 to come into electrical connection with the first and second source/drain patterns SD1 and SD2. A gate contact GC may be formed to penetrate the second interlayer dielectric layer 120 and the gate capping pattern GP to come into electrical connection with the gate electrode GE.

For example, the formation of each of the upper active contact AC and the gate contact GC may include forming a barrier pattern and forming a conductive pattern on the barrier pattern. The barrier pattern may be conformally formed and may include a metal layer and a metal nitride layer. The conductive pattern may include a low-resistance metal. Separation structures DB may be formed to penetrate the first and second interlayer dielectric layers 110 and 120 and the gate electrode GE. The separation structures DB may penetrate the gate electrode GE to extend into the active pattern AP1 or AP2. The separation structures DB may include a silicon-based dielectric material, such as a silicon oxide layer or a silicon nitride layer.

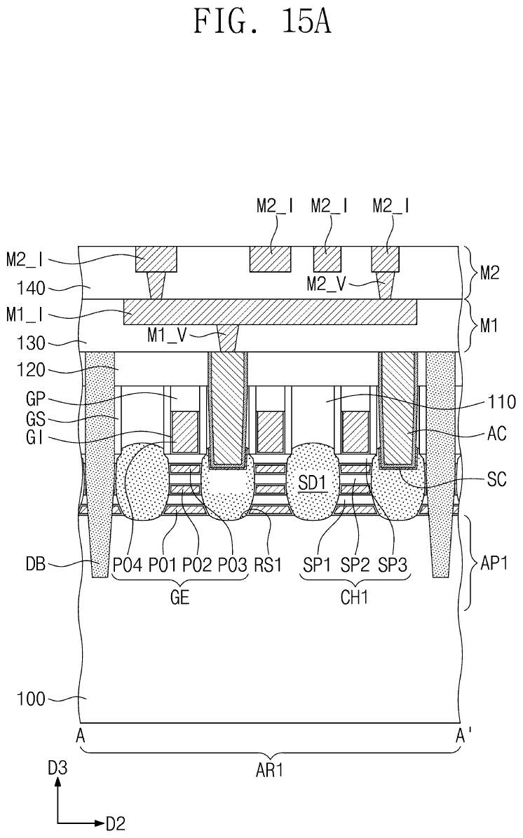

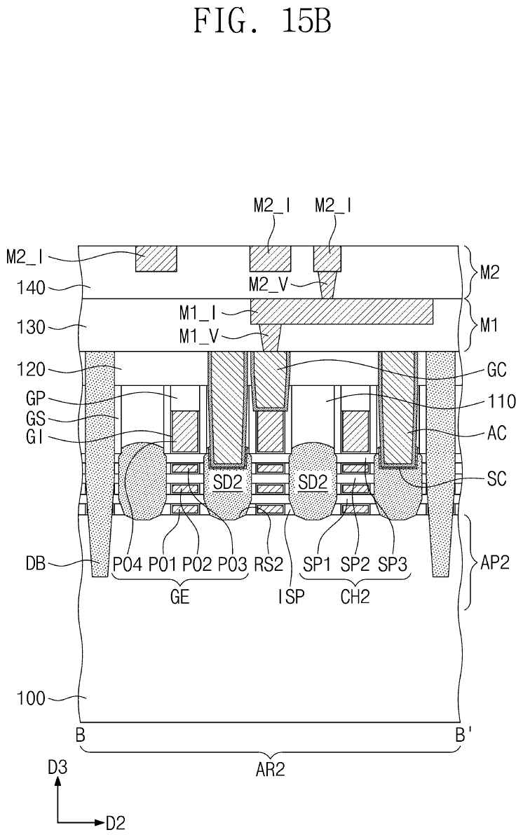

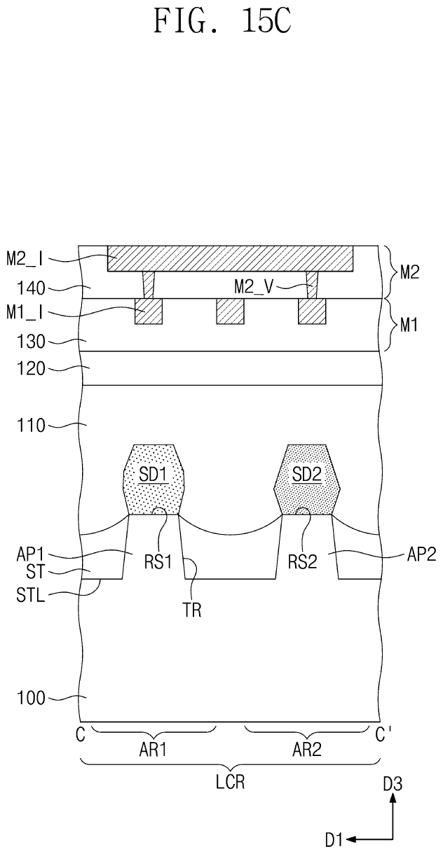

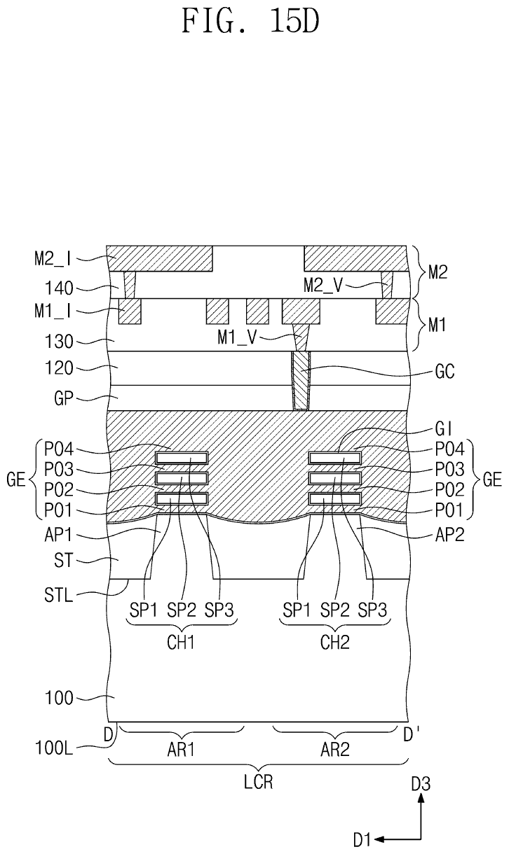

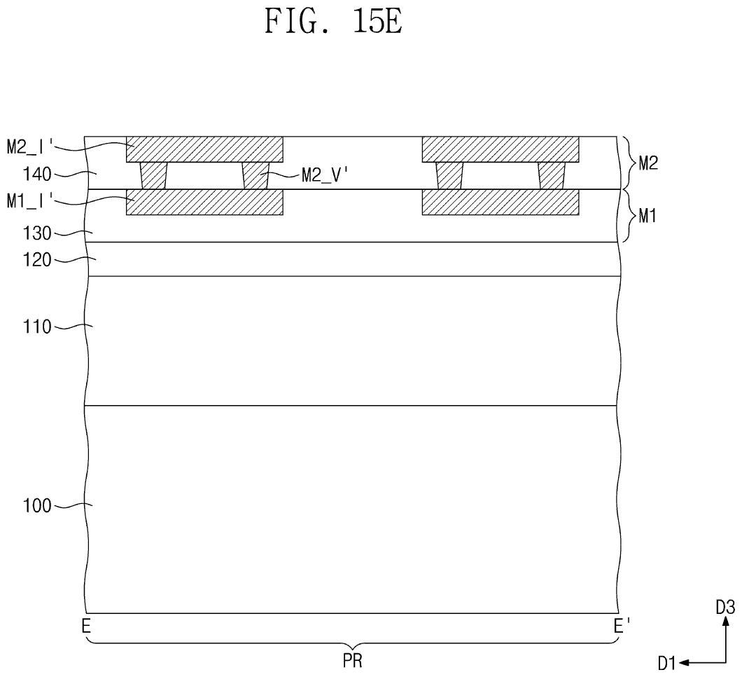

Referring to FIGS. 15A, 15B, 15C, 15D, and 15E, a first upper dielectric layer 130 may be formed on the logic cell region LCR and the peripheral region PR of the substrate 100. The first upper dielectric layer 130 may cover the second interlayer dielectric layer 120. For example, the first upper dielectric layer 130 may include a silicon-based dielectric material.

A first upper metal layer M1 may be formed in the first upper dielectric layer 130. For example, the formation of the first upper metal layer M1 may include forming first upper wiring lines M1_I and M1_V provided on the logic cell region LCR and first peripheral upper wiring lines M1_I′ provided on the peripheral region PR. The formation of the first upper wiring lines M1_I and M1_V may include forming a contact hole and a trench that penetrate the first upper dielectric layer 130, and depositing a conductive material that fills the contact hole and the trench. The formation of the first peripheral upper wiring lines M1_I′ may include forming a trench that penetrates the first upper dielectric layer 130, and depositing a conductive material that fills the trench. The first upper wiring lines M1_I and M1_V and the first peripheral upper wiring lines M1_I′ may be formed simultaneously with each other.

A second upper dielectric layer 140 may be formed on the first upper dielectric layer 130. The second upper dielectric layer 140 may cover the first upper dielectric layer 130. For example, the second upper dielectric layer 140 may include a silicon-based dielectric material.

A second upper metal layer M2, which is connected to the first upper metal layer M1, may be formed in the second upper dielectric layer 140. For example, the formation of the second upper metal layer M2 may include forming second upper wiring lines M2_I and M2_V provided on the logic cell region LCR and second peripheral upper wiring lines M2_I′ and M2_V′ provided on the peripheral region PR. The formation of the second upper wiring lines M2_I and M2_V may include forming a contact hole and a trench that penetrate the second upper dielectric layer 140, and depositing a conductive material that fills the contact hole and the trench. The formation of the second peripheral upper wiring lines M2_I′ and M2_V′ may include forming a contact hole and a trench that penetrate the second upper dielectric layer 140, and depositing a conductive material that fills the contact hole and the trench. The second upper wiring lines M2_I and M2_V and the second peripheral upper wiring lines M2_I′ and M2_V′ may be formed simultaneously with each other.

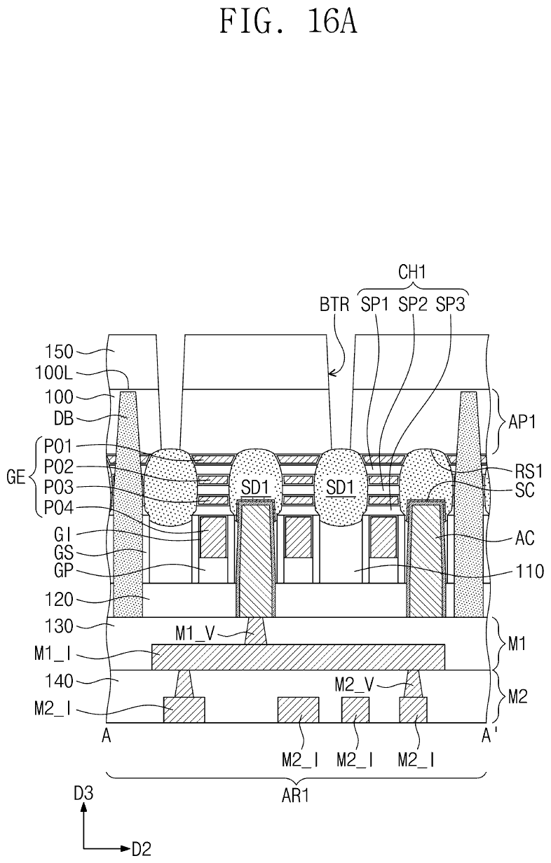

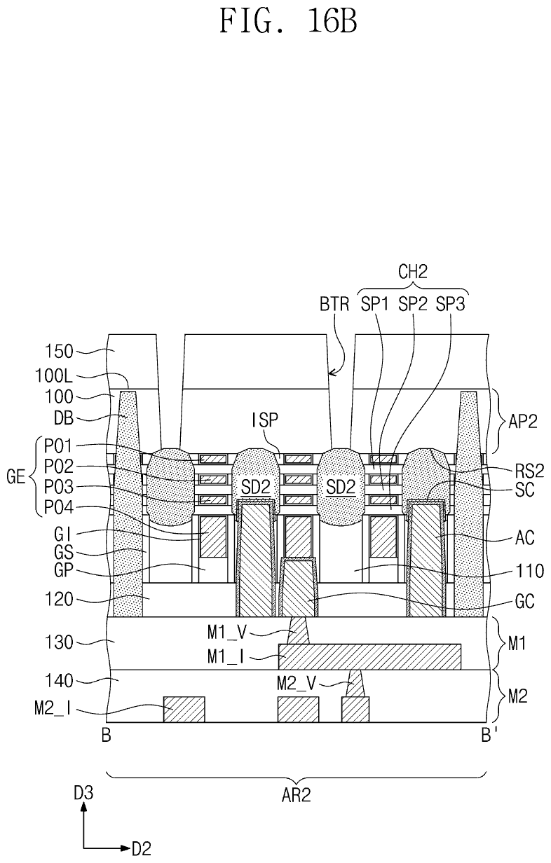

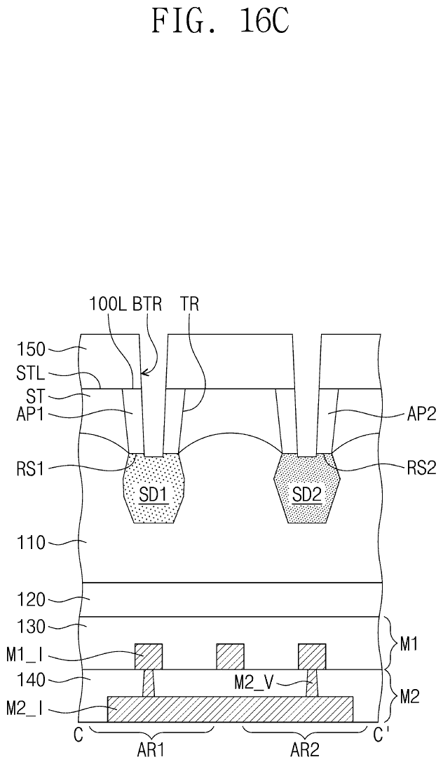

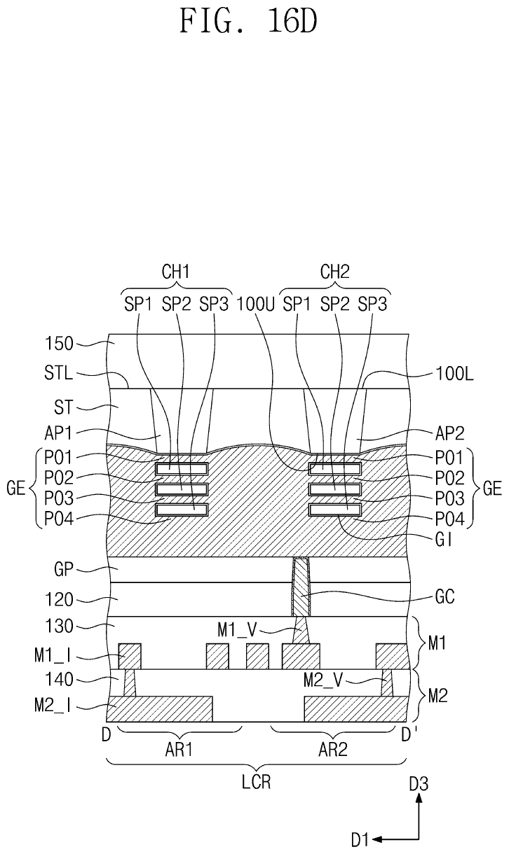

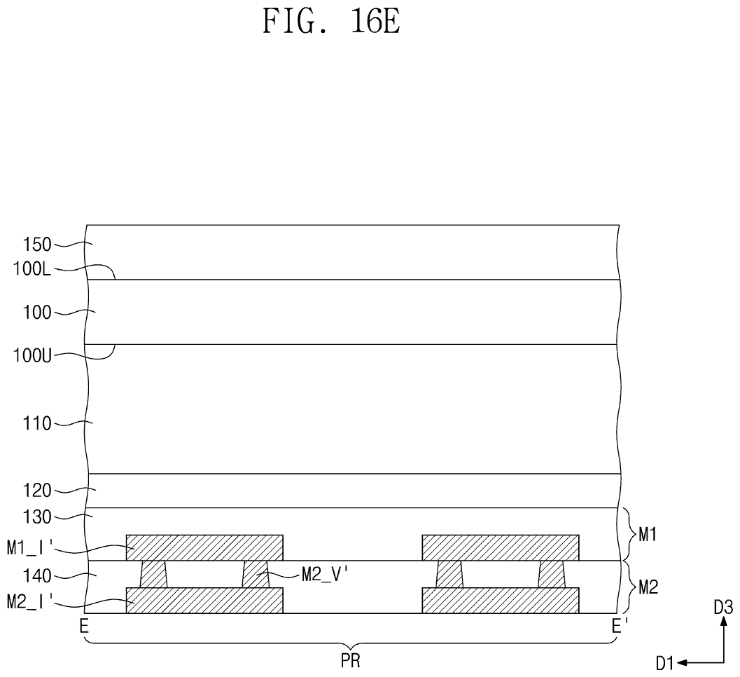

Referring to FIGS. 16A, 16B, 16C, 16D, and 16E, the substrate 100 may be turned upside down to expose a bottom surface 100L of the substrate 100. The exposed substrate 100 may be partially removed. For example, a planarization process may remove a portion of the substrate 100, and a thickness of the substrate 100 may be reduced. In addition, a top surface of the device isolation layer ST may be exposed. After that, a third interlayer dielectric layer 150 may be formed on the bottom surface 100L of the substrate 100. The third interlayer dielectric layer 150 may be formed below the logic cell region LCR and the peripheral region PR of the substrate 100.

Thereafter, on the logic cell region LCR, a mask pattern may be used such that the third interlayer dielectric layer 150 and the substrate 100 may be patterned to form backside trenches BTR. The backside trenches BTR may extend in the first direction D1 and may be spaced apart from each other in the second direction D2.

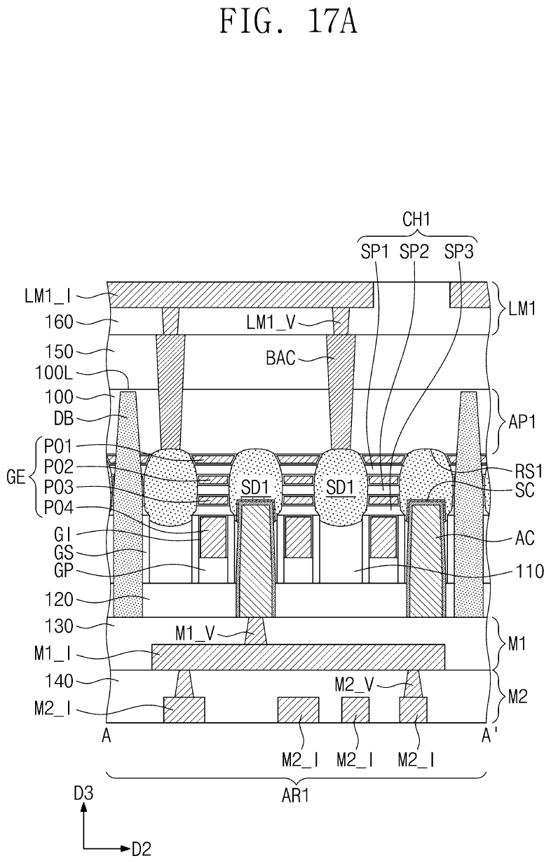

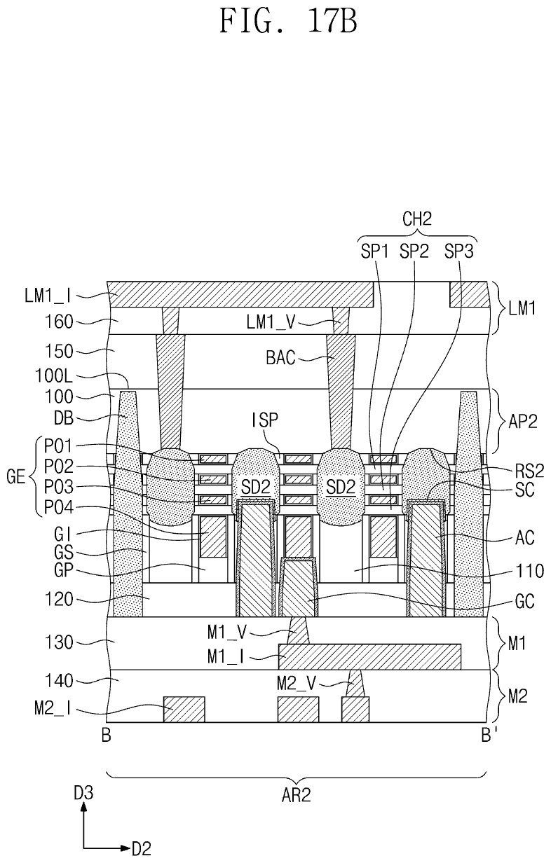

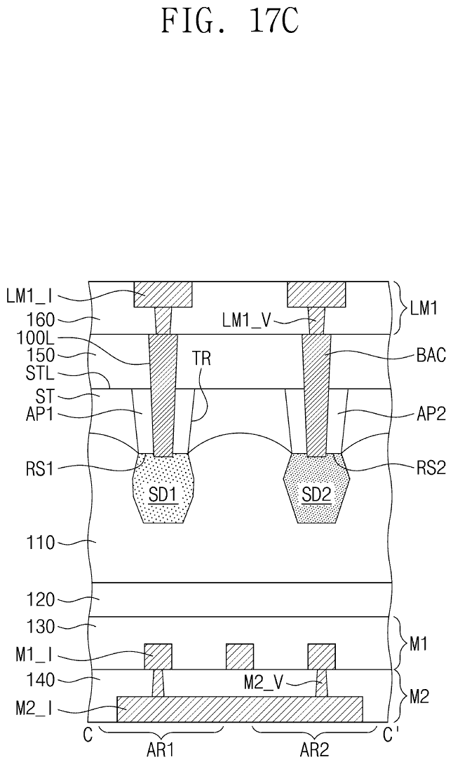

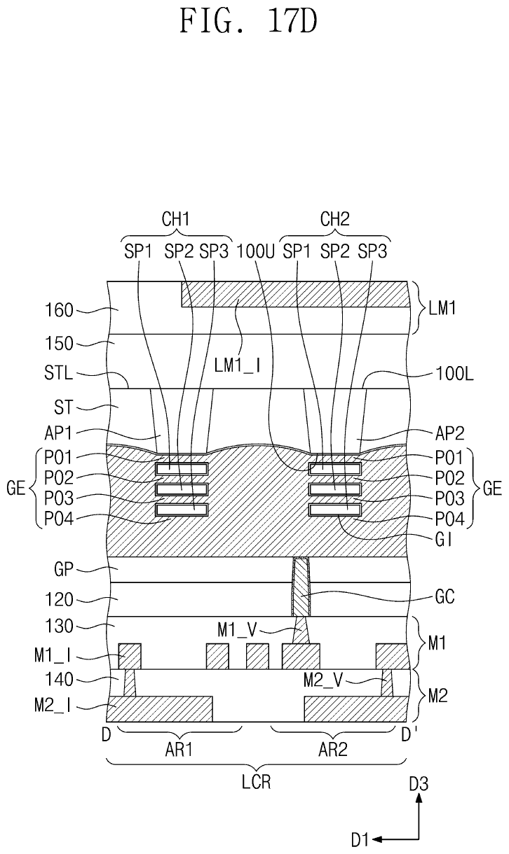

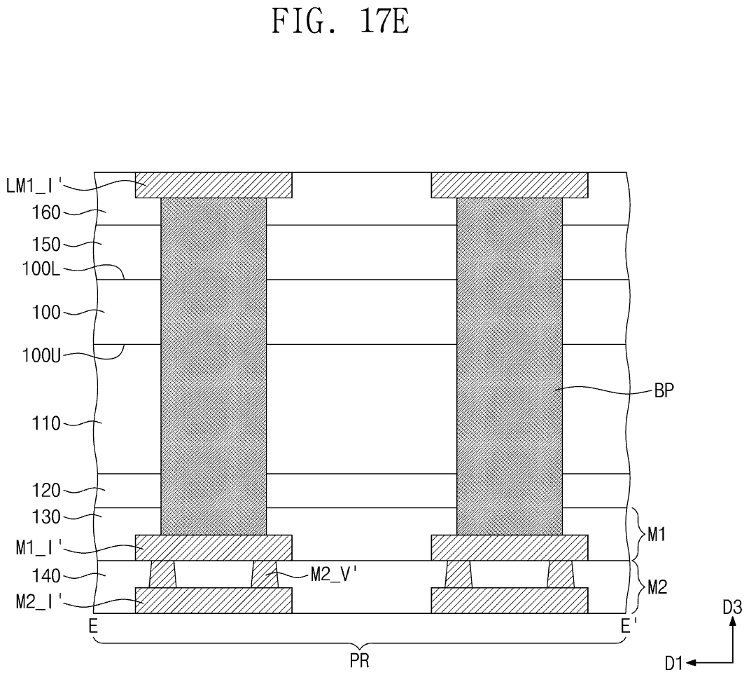

Referring to FIGS. 17A, 17B, 17C, 17D, and 17E, lower active contacts BAC may be formed. The formation of the lower active contacts BAC may include depositing conductive materials in the backside trenches (see BTR of FIG. 16A).

A first lower dielectric layer 160 may be formed on the third interlayer dielectric layer 150. The first lower dielectric layer 160 may be formed on a backside of the logic cell region LCR and the peripheral region PR of the substrate 100. For example, the first lower dielectric layer 160 may include a silicon-based dielectric material.

A conductive structure BP may be formed to penetrate the peripheral region PR of the substrate 100. The formation of the conductive structure BP may include forming a through hole that penetrates the first lower dielectric layer 160, the substrate 100, the first, second, and third interlayer dielectric layers 110, 120, and 150, and a portion of the first upper dielectric layer 130 to expose the first peripheral upper wiring lines M1_I′, and depositing a conductive material to fill the through hole. During the deposition of the conductive material, the conductive material may not fill to a level that same as that of a bottom surface of the first lower dielectric layer 160. For example, the conductive material may not fill to a level between top and bottom surfaces of the first lower dielectric layer 160.

In fabricating a semiconductor device that includes subsequently described lower dielectric layers 160, 170, and 180 and the lower active contact BAC, it may be difficult to form a through via that penetrates the substrate 100. For example, since it may be required to connect a first through via that penetrates a backside of the substrate 100 to a second through via that penetrates the following lower dielectric layers 160, 170, and 180, there may be an increase in complexity of fabrication process. In contrast, according to some embodiments of the present inventive concepts, as discussed below, before the formation of a first lower metal layer LM1, a conductive structure BP may be formed as a single unitary piece or member on the peripheral region PR of the substrate 100, and may be connected to peripheral upper wiring lines M1_I′, M2_I′, and M2_V′ and peripheral lower wiring lines LM1_I′, LM2_I′, LM2_V′, LM3_I′, and LM3_V′ to thereby serve as a through via, with the result that fabrication process may become relatively simplified.

A first lower metal layer LM1 may be formed in the first lower dielectric layer 160. For example, the formation of the first lower metal layer LM1 may include forming first lower wiring lines LM1_I and LM1_V provided on the logic cell region LCR and first peripheral lower wiring lines LM1_I′ provided on the peripheral region PR. The formation of the first lower wiring lines M1_I and M1_V may include forming a contact hole and a trench that penetrate the first lower dielectric layer 160, and depositing a conductive material that fills the contact hole and the trench. The formation of the first peripheral lower wiring lines LM1_I′ may include forming a trench that penetrates the first lower dielectric layer 160, and depositing a conductive material that fills the trench. During the formation of the first peripheral lower wiring lines LM1_I′, the trench may expose a bottom surface of the conductive structure BP, and the first peripheral lower wiring lines LM1_I′ may have a direct connection with the conductive structure BP. For example, the first lower wiring lines LM1_I and LM1_V and the first peripheral lower wiring lines LM1_I′ may be formed simultaneously with each other.

Referring back to FIGS. 4 and 5A 5B, 5C, 5D, and 5E, a second lower dielectric layer 170 may be formed on a rear surface of the first lower dielectric layer 160. The second lower dielectric layer 170 may cover the first lower dielectric layer 160. For example, the second lower dielectric layer 170 may include a silicon-based dielectric material.

A second lower metal layer LM2, which is connected to the first lower metal layer LM1, may be formed in the second lower dielectric layer 170. For example, the formation of the second lower metal layer LM2 may include forming second lower wiring lines LM2_I and LM2_V provided on the logic cell region LCR and second peripheral lower wiring lines LM2_I′ and LM2_V′ provided on the peripheral region PR. The formation of the second lower wiring lines LM2_I and LM2_V may include forming a contact hole and a trench that penetrate the second lower dielectric layer 170, and depositing a conductive material that fills the contact hole and the trench. The formation of the second peripheral lower wiring lines LM2_I′ and LM2_V′ may include forming a contact hole and a trench that penetrate the second lower dielectric layer 170, and depositing a conductive material that fills the contact hole and the trench. The second lower wiring lines LM2_I and LM2_V and the second peripheral lower wiring lines LM2_I′ and LM2_V′ may be formed simultaneously with each other.

A third lower dielectric layer 180 may be formed on a rear surface of the second lower dielectric layer 170. The third lower dielectric layer 180 may cover the second lower dielectric layer 170. For example, the third lower dielectric layer 180 may include a silicon-based dielectric material.

A third lower metal layer LM3, which is connected to the second lower metal layer LM2, may be formed in the third lower dielectric layer 180. For example, the formation of the third lower metal layer LM3 may include forming third lower wiring lines LM3_I and LM3_V provided on the logic cell region LCR and third peripheral lower wiring lines LM3_I′ and LM3_V′ provided on the peripheral region PR. During the formation of the third lower wiring lines LM3_I and LM3_V, first and second power lines VSS and VDD may be formed. The first and second power lines VSS and VDD may be formed in the third lower dielectric layer 180, and may be electrically connected to the first, second, and third lower wiring lines LM1_I, LM1_V, LM2_I, LM2_V, LM3_I, and LM3_V. The first, second, and third lower metal layers LM1, LM2, and LM3 may be formed to constitute a power delivery network layer PDN.

A semiconductor device according to some embodiments of the present inventive concepts may include a conductive structure that penetrates a peripheral region of a substrate. The conductive structure may be connected (e.g., directly) to peripheral upper wiring lines on the peripheral region and to peripheral lower wiring lines below the peripheral region. For example, the peripheral upper wiring lines, the conductive structure, and the peripheral lower wiring lines may be electrically connected to vertically penetrate the semiconductor device, and may collectively serve as a substitute for a through via (TSV). According to some embodiments of the present inventive concepts, fabrication operations for forming through vias that vertically penetrate the semiconductor device may be omitted. The conductive structure may be formed simultaneously with the formation of wiring lines on a rear surface of the semiconductor device, and thus fabrication processes may be simplified.

Although the present inventive concepts have been described in connection with some embodiments of the present inventive concepts illustrated in the accompanying drawings, it will be understood by one of ordinary skill in the art that variations in form and detail may be made therein without departing from the present inventive concepts. The above disclosed embodiments should thus be considered illustrative and not restrictive.

What is claimed is:

1. A semiconductor device, comprising:
a substrate comprising a logic cell region and a peripheral region extending around the logic cell region;
a logic device in the logic cell region and comprising a plurality of source/drain patterns;
an upper active contact on and electrically connected to one of the source/drain patterns;
a lower active contact below and electrically connected to another of the source/drain patterns;
a conductive structure that penetrates the peripheral region of the substrate;
a plurality of peripheral upper wiring lines in the peripheral region and connected to the conductive structure; and
a plurality of peripheral lower wiring lines in the peripheral region and connected to the conductive structure opposite the peripheral upper wiring lines,
wherein a bottom surface of the conductive structure is lower than a bottom surface of the lower active contact, relative to a bottom surface of the substrate.

2. The semiconductor device of claim 1, wherein the bottom surface of the substrate is parallel to a first direction, and wherein the conductive structure has a width in the first direction ranging from about 400 nm to about 600 nm.

3. The semiconductor device of claim 1, further comprising:
a first upper dielectric layer on a top surface of the substrate and on a top surface of the upper active contact, and a second upper dielectric layer stacked on the first upper dielectric layer,
wherein the conductive structure penetrates at least a portion of the first upper dielectric layer.

4. The semiconductor device of claim 3, wherein the peripheral upper wiring lines comprise:
a first peripheral upper line pattern in the first upper dielectric layer and directly connected to the conductive structure; and
a second peripheral upper line pattern in the second upper dielectric layer and electrically connected to the first peripheral upper line pattern,
wherein, in plan view, the conductive structure overlaps the first and second peripheral upper line patterns.

5. The semiconductor device of claim 4, wherein the bottom surface of the substrate is parallel to a first direction, and wherein a width in the first direction of the first peripheral upper line pattern is greater than a width in the first direction of the conductive structure.

6. The semiconductor device of claim 3, further comprising:
a first upper via that penetrates a portion of the first upper dielectric layer and is electrically connected to the upper active contact,
wherein a top surface of the conductive structure is coplanar with a top surface of the first upper via.

7. The semiconductor device of claim 1, wherein a top surface of the conductive structure is higher than a top surface of the upper active contact, relative to a top surface of the substrate that is opposite the bottom surface of the substrate.

8. The semiconductor device of claim 1, further comprising:
a first lower dielectric layer on the bottom surface of the substrate and on the bottom surface of the lower active contact,
wherein the conductive structure penetrates at least a portion of the first lower dielectric layer.

9. The semiconductor device of claim 8, wherein the peripheral lower wiring lines comprise a first peripheral lower line pattern in the first lower dielectric layer and directly connected to the conductive structure,
wherein, in plan view, the conductive structure overlaps the first peripheral lower line pattern.

10. The semiconductor device of claim 8, further comprising:
a first lower via that penetrates a portion of the first lower dielectric layer and has is electrically connected to the lower active contact,
wherein the bottom surface of the conductive structure is coplanar with a bottom surface of the first lower via.

11. The semiconductor device of claim 1, wherein the conductive structure comprises a plurality of conductive structures, and wherein, in plan view, each of the plurality of conductive structures are spaced apart from each other in a first direction and a second direction that are parallel to a bottom surface of the substrate, the second direction intersecting the first direction.

12. The semiconductor device of claim 1, further comprising:
a first external connection terminal directly connected to an uppermost one of the peripheral upper wiring lines; and
a second external connection terminal directly connected to a lowermost one of the peripheral lower wiring lines.

13. A semiconductor device, comprising:
a substrate that comprises a logic cell region and a peripheral region extending around the logic cell region;
a plurality of source/drain patterns on the logic cell region;
a channel pattern between ones of the source/drain patterns and comprising a plurality of semiconductor patterns that are stacked and spaced apart from each other in a direction perpendicular to a top surface of the substrate;
a gate electrode on the channel pattern;
a gate capping pattern on a top surface of the gate electrode opposite the channel pattern;
a first interlayer dielectric layer on the top surface of the substrate and on the source/drain patterns;
a second interlayer dielectric layer that on a top surface of the first interlayer dielectric layer and on a top surface of the gate capping pattern;
a third interlayer dielectric layer on a bottom surface of the substrate that is opposite the top surface of the substrate;
a plurality of upper active contacts that penetrate the first and second interlayer dielectric layers and are electrically connected to a first subset of the source/drain patterns;
a plurality of lower active contacts that penetrate the third interlayer dielectric layer and the substrate and are electrically connected to a second subset of the source/drain patterns;
first and second upper dielectric layers that are sequentially stacked on a top surface of the second interlayer dielectric layer;
first, second, and third lower dielectric layers that are sequentially stacked on a bottom surface of the third interlayer dielectric layer;
a conductive structure that penetrates the peripheral region of the substrate and the first, second, and third interlayer dielectric layers;
a plurality of peripheral upper wiring lines in the peripheral region, wherein the peripheral upper wiring lines penetrate the first and second upper dielectric layers to connect to the conductive structure; and
a plurality of peripheral lower wiring lines in the peripheral region, wherein the peripheral lower wiring lines penetrate the first, second, and third lower dielectric layers to connect to the conductive structure opposite the peripheral upper wiring lines,
wherein the conductive structure penetrates the first upper dielectric layer and at least a portion of the first lower dielectric layer.

14. The semiconductor device of claim 13, wherein a top surface of the conductive structure is higher than top surfaces of the upper active contacts, relative to the top surface of the substrate, and
wherein a bottom surface of the conductive structure is lower than bottom surfaces of the lower active contacts, relative to the bottom surface of the substrate.

15. The semiconductor device of claim 13, wherein the bottom surface of the substrate is parallel to a first direction, and wherein the conductive structure has width in the first direction ranging from about 400 nm to about 600 nm.

16. The semiconductor device of claim 13, further comprising:
a power line in at least one of the first, second, or third lower dielectric layers, wherein the power line is electrically connected to one or more of the lower active contacts.

17. A semiconductor device, comprising:
a redistribution substrate; and
a first semiconductor chip and a second semiconductor chip stacked on the redistribution substrate, such that the first semiconductor chip is between the redistribution substrate and the second semiconductor chip,
wherein the first semiconductor chip comprises:
a substrate that comprises a logic cell region and a peripheral region extending around the logic cell region;
a plurality of source/drain patterns in the logic cell region;
a channel pattern between ones of the source/drain patterns, wherein the channel pattern comprises a plurality of semiconductor patterns that are stacked and spaced apart from each other in a direction perpendicular to a top surface of the substrate;
a plurality of upper active contacts on and electrically connected to a first subset of the source/drain patterns;
a plurality of lower active contacts on and electrically connected to a second subset of the source/drain patterns;
a conductive structure that penetrates the peripheral region of the substrate;
a plurality of peripheral upper wiring lines in the peripheral region of the substrate and connected to the conductive structure; and
a plurality of peripheral lower wiring lines in the peripheral region of the substrate and electrically connected to the conductive structure opposite the peripheral upper wiring lines,
wherein the conductive structure, the peripheral upper wiring lines, and the peripheral lower wiring lines electrically connect the redistribution substrate and the second semiconductor chip to each other.

18. The semiconductor device of claim 17, further comprising:
a first external connection terminal between the first semiconductor chip and the second semiconductor chip; and
a second external connection terminal between the first semiconductor chip and the redistribution substrate,
wherein the peripheral upper wiring lines are electrically connected to the first external connection terminal, and
wherein the peripheral lower wiring lines are electrically connected to the second external connection terminal.

19. The semiconductor device of claim 17, wherein
a top surface of the conductive structure is higher than top surfaces of the upper active contacts, relative to the top surface of the substrate, and
wherein a bottom surface of the conductive structure is lower than bottom surfaces of the lower active contacts, relative to a bottom surface of the substrate that is opposite the top surface of the substrate.

20. The semiconductor device of claim 17, further comprising:
a third semiconductor chip on the redistribution substrate and laterally spaced apart from the first and second semiconductor chips.
